(19) United States
(12) Patent Application Publication
(10) Pub. No.: US 2026/0087220 A1
(43) Pub. Date: Mar. 26, 2026

(54) METHOD FOR CARRYING OUT AN OPTIMIZATION OF AT LEAST ONE SPECIFIC SIGNAL PATH OF A CIRCUIT DESIGN TO BE MAPPED IN AN FPGA, AND SOFTWARE FOR GENERATING A CIRCUIT DESIGN TO BE MAPPED IN AN FPGA

(71) Applicant: dSPACE GmbH, Paderborn (DE)

(72) Inventors: Heiko KALTE, Paderborn (DE); Dominik LUBELEY, Verl (DE)

(73) Assignee: dSPACE GmbH, Paderborn (DE)

(21) Appl. No.: 19/338,341

(22) Filed: Sep. 24, 2025

(30) Foreign Application Priority Data
Sep. 24, 2024 (DE) 10 2024 127 513.8

(51) Int. Cl. G06F 30/347

(52) U.S. Cl. CPC G06F 30/347

(57) ABSTRACT

A method for carrying out an optimization of at least one specific signal path of a circuit design to be mapped in an FPGA. The at least one specific signal path in the circuit design to be mapped is defined as a multi-cycle path having an effective clock rate. Provided also is software for generating a circuit design to be mapped in an FPGA, a device for processing data, an input FPGA interface block for software for generating a circuit design to be mapped in an FPGA, and output FPGA interface block for software for generating a circuit design to be mapped in an FPGA, a circuit design to be mapped in an FPGA, and an FPGA having a circuit design mapped therein.

This nonprovisional application claims priority under 35 U.S.C. 119(a) to German Patent Application No. 102024127 513.8, which was filed in Germany on Sep. 24, 2024, and which is herein incorporated by reference.

### BACKGROUND OF THE INVENTION

### FIELD OF THE INVENTION

The present invention relates to methods for carrying out an optimization of at least one specific signal path of a circuit design to be mapped in an FPGA, in that the at least one specific signal path in the circuit design to be mapped is defined as a multi-cycle path having an effective clock rate. The present invention also relates to software for generating a circuit design to be mapped in an FPGA, a device for processing data, an input FPGA interface block for software for generating a circuit design to be mapped in an FPGA, and output FPGA interface block for software for generating a circuit design to be mapped in an FPGA, a circuit design to be mapped in an FPGA, as well as an FPGA having a circuit design mapped therein.

### Description of the Background Art

In digital circuit technology, synchronous circuit designs are commonly used when implementing field programmable gate arrays (FPGAs). With the aid of pipelining as a design technique, a new input value may be taken over in a signal path with each clock of a clock frequency. After a startup time, with each new clock, a new output value is correspondingly present as the result at the end of the signal path. A high data throughput may be made possible thereby, and timing errors may be avoided. Nevertheless, the latency of the signal paths may increase thereby for synchronous designs. In many applications of FPGAs, such as when regulating electric motors or in power electronics, there is, however, often the desire to keep the latency of signal paths low.

### SUMMARY OF THE INVENTION

The object of the present invention is therefore to overcome the described disadvantages of the prior art and, in particular, to specify means with which an optimization of a circuit design to be mapped in an FPGA may be carried out.

According to a first aspect, the object is achieved by the invention in that a method is proposed for carrying out an optimization of at least one specific signal path of a circuit design to be mapped in an FPGA. The method comprises the fact that (i) a timing analysis is at least partially carried out for at least one part of the circuit design to be mapped, and one or multiple signal paths of the circuit design is or are selected as the at least one specific signal path from among those signal paths of the circuit design to be mapped for which a timing error is detected during the timing analysis, the at least one specific signal path in the circuit design to be mapped being defined as a multi-cycle path having an effective clock rate which is different than a base clock frequency, at which the at least one specific signal path is clocked as a standard according to the circuit design to be mapped, the effective clock rate being set in the circuit design at least partially and/or at least implicitly based on a specific downsampling factor applied, in particular, to the base clock frequency, and/or (ii) one or multiple signal paths of the circuit design is or are selected as the at least one specific signal path, the at least one specific signal path in the circuit design to be mapped being defined as a multi-cycle path having an effective clock rate which is different from the base clock frequency with which the at least one specific signal path is clocked according to the circuit design to be mapped, the effective clock rate being set in the circuit design at least partially and/or at least implicitly based on a specific downsampling factor applied, in particular, to the base clock frequency.

The invention is thus based on the surprising finding that more time may be granted for the logic calculation by defining a signal path of the circuit design as a multi-cycle path in this specific signal path. The number of registers, and thus the sum of the timing reserves between consecutive registers, may be reduced in the particular specific signal path. In this way, the latency of a data signal along the particular specific signal path may be easily and reliably reduced. The circuit design may be advantageous optimized thereby.

In particular, the latency of the specific signal path may be reduced thereby without any adaptations to the remaining parts of the circuit design being necessary. The specific signal paths may therefore be decoupled to a certain extent from other signal paths with respect to the clock rate.

The proposed method thus makes it possible to generally select, for the circuit design, a comparatively high clock rate according to the base clock frequency and thus generally permit a higher data throughput. And yet a clock rate which deviates from the base clock frequency, in particular in a reduced manner, may nevertheless be set in the at least one specific signal path in which an optimization of the latency is desired.

At least two, preferably exactly two, registers are preferably assigned to at least each specific signal path, in particular to each signal path of the circuit design, in particular at the beginning of the timing analysis, in particular, at least one, preferably exactly one, register being assigned in each case at the beginning of the particular signal path, and at least one, preferably exactly one, register being assigned in each case at the end of the particular signal path. One or multiple common register(s) may also be assigned to at least two of the signal paths. If only two registers are provided in the specific signal path, all logic calculations of the specific signal path are advantageously provided between the two registers in the direction of signal flow. This is advantageous, since in many cases a timing error may be provoked thereby in a targeted manner in the timing analysis. The reason for this is that, as a rule, the logic calculations in the specific signal path require a longer time duration than a period of the base clock frequency. Based on the timing error, and by incorporating any pieces of information obtained thereby, in particular for the execution duration of the logic calculations, a clock rate which is reduced compared to the base clock frequency may be ascertained as the effective clock rate, whose inverse corresponds at least to the delay of the specific signal path, i.e., the duration of the logic calculations. A suitable specific downsampling factor may be selected for this purpose to set the effective clock rate accordingly.

The at least one specific signal path is preferably part of the at least one part of the circuit design to be mapped, for which the timing analysis is at least partially carried out.

The ratio of the base clock frequency and the effective clock rate at which the particular specific signal path is clocked is advantageously described by the, in particular integral, downsampling factor.

The sum of the timing reserves between consecutive registers in a signal path is also referred to as slack. Negative values of slack indicate a time shortfall, positive values of slack indicate a time surplus. If only two registers are provided in a signal path, the timing reserve is identical to the slack of the signal path as a special case. As an aside and to avoid confusion, it should be noted that the designation of “timing reserve” in the present application is also sometimes referred to as “slack” in the prior art.

In the present application, the base clock frequency is preferably understood to be a clock at which the particular specific signal path would be clocked according to the circuit design if it were not a multi-cycle path. The base clock frequency may be predefined, for example, within an interval dependent on an FPGA chip.

In the present application, an effective clock rate of a specific signal path defined as a multi-cycle path is preferably understood to be a clock at which the registers of the particular specific signal path are executed by a chip enable signal and which is lower than the base clock frequency. In particular, the registers of the particular specific signal path are executed by a chip enable signal only every nth base clock frequency, using n of the specific downsampling factor. The effective clock rate thus represents an execution clock controlled by the chip enable signal in the multi-cycle path. The (at least partial and/or implicit) application of the downsampling factor to the base clock frequency is therefore advantageously implemented by the chip enable signal (generated in keeping with the downsampling factor), in particular with the result that the effective clock rate is set. However, it may also be alternatively or additionally advantageous that, in the case of at least one or multiple or all specific signal paths defined as multi-cycle paths, an effective clock rate is preferably understood to be a clock which represents a clock frequency separate from the base clock frequency and is lower than the base clock frequency.

In that the, in particular integral, specific downsampling factor n is applied to base clock frequency f_{base} (in particular, in the mathematical sense), effective clock rate f_{eff} is obtained as f_{eff} = f_{base} / n.

It is known to those skilled in the art that not all signal paths which cause a timing error during the timing analysis must necessarily also be optimized according to the proposed method, and therefore not all these signal paths must simultaneously also be specific signal paths. The timing errors of the remaining signal paths may then be eliminated, for example, using other and/or conventional measures, for example in that additional registers are provided in the signal path at the cost of the latency.

It is particularly advantageous if the proposed method is carried out during a phase in which the circuit design is being drafted and/or tested.

The timing analysis can be carried out before and/or during a carrying out of a build operation of the circuit design to be mapped. The build operation may end prematurely, for example based on a result of the timing analysis (for example, based on the occurrence of a timing error).

A signal path defined as a multi-cycle path in the circuit design and having an effective clock rate is carried out at the effective clock rate in the FPGA at runtime after the circuit design was mapped in the FPGA.

The terms “clock,” clock rate,” and “clock frequency” are used synonymously in this application unless otherwise apparent from the particular context.

No register or only one register in each case at the beginning and/or end of the specific signal path is preferably assigned to the specific signal path, in particular as part in each case of an interface provided there and assigned to the specific signal path. In particular, the logic calculations carried out in the specific signal path are provided along the signal flow between the two registers. More than two registers may optionally also be provided in the specific signal path.

The effective clock rate is advantageously also set in the circuit design at least partially and/or at least implicitly based on a specific upsampling factors corresponding to the specific downsampling factor (in particular, having the same value) applied, in particular, to the base clock frequency. In other words, the specific signal path in the circuit design to be mapped is advantageously defined thereby as a multi-cycle path having the effective clock rate, in that a downsampling is carried out according to the specific downsampling factor at the beginning of the specific signal path, and an upsampling is carried out according to the specific upsampling factor at the end of the specific signal path. If a downsampling is carried out by a factor n, the upsampling is also advantageously carried out by the same factor n.

The proposed method is therefore suitable, in particular, for carrying out an optimization of circuit designs, which are associated with a regulation of electric motors or power electronics.

A typical and preferred application, to which the invention (and thus, in particular, also the method according to the first aspect of the invention) is, however, not limited, is HIL simulation, so-called hardware-in-the-loop simulation. Control units, for example motor vehicle control units, are subjected to a test for correct functioning, for which purpose the control unit to be tested is connected to a circuit in order to apply signals to the control unit via the circuit and/or to capture signals thereby.

The software model of a test environment runs on a simulation environment for this purpose, for example the simulation of a drive in the case of a motor vehicle. Simulated results are applied to the output channels, for example the pins or registers of the output channels of the circuit, by electrical signals representing the results to thereby transfer them to the control unit, and/or signals are applied to the input channels, for example to pins or registers of the input channels of the circuit, by the control unit to thereby be able to capture and process them in the simulation environment. A control unit may thus be operated in a simulation environment as though it were actually being operated in the real environment.

The simulation environment, or simulator for short, is formed, for example, by a real-time computer system having at least one processor, which processes the software model. For example, the model may be provided by real-time-capable software or a multiplicity of interacting software tools, which preferably has a graphical user interface and is particularly preferably programmed with the aid of software objects. The software may comprise MATLAB, Simulink or also RTI (Real-Time Interface) of the applicant, which forms, for example, a connecting element to Simulink. In the aforementioned cases, software objects are programmed, for example, graphically as a block, in particular in a hierarchical manner. However, a simulation environment is not limited to the use of this software, which is mentioned as an example. The software model is executable on the simulation environment either directly after programming or after code generation and compilation.

In addition to the processor circuit, which comprises the at least one processor, the simulation environment also frequently comprises at least one I/O circuit connected to the processor circuit, which has the aforementioned input/output channels. It may also be provided that at least one I/O circuit of this type, which comprises input and/or output channels, is connected to a circuit comprising a programmable logic chip, in particular a field programmable gate array (FPGA), to obtain signals therefrom or to provide them thereto. The FPGA circuit, in turn, may be connected to the processor circuit, so that the simulation model may be executed partially on the FPGA circuit and partially on the processor circuit. The input/output channels may have switch-selectable sampling rates, so that rapidly variable signals, for example, may be measured more frequently than slowly variable signals. A sampling rate f may also be expressed in the form of a sampling period T corresponding over T=1/f.

A real-time computer system differs from commercially available computer systems, in particular, in that a predefined latency is not exceeded, for example between the input of a changed sensor signal and the response resulting therefrom, such as the output of a changed actuation signal. Depending on the system to be simulated, a maximum latency of, for example, 1 millisecond or shorter may be necessary. In particular, a simulation of the drive of an electrical vehicle (e-drive) or for a simulation of power electronics imposes strict requirements on the speed of the control loop, in particular with maximum permissible latencies in the range of microseconds, so that real-time simulations are frequently no longer covered by pure processor models and processor-controlled I/O channels, but instead the time-critical model parts are executed on a freely programmable FPGA circuit. The FPGA circuit is preferably designed in such a way that different I/O circuits may be connected thereto in a modular manner. A circuit design according to the invention or an optimized circuit design according to the present invention may advantageously be mapped in the freely programmable FPGA circuit.

Alternatively or additionally, it may also be provided that a delay of a data signal along the at least one specific signal path is at least implicitly ascertained, and the specific downsampling factor is at least partially and/or at least implicitly set based on the base clock frequency and/or the ascertained delay.

The effective clock rate for the particular specific signal path may be particularly easily set thereby. Indeed, the specific downsampling factor may be ascertained based on the delay and the base clock frequency, which is generally known. For this purpose, the delay may be ascertained, for example, during the timing analysis, as already described above.

For example, the specific downsampling factor may be selected for the specific signal path as a natural number having the smallest possible value greater than zero in such a way that the inverse of the effective clock rate is greater than or equal to the delay. If the delay of the specific signal path is, for example, 67 ns, and the base clock frequency is 0.1 GHz (with a corresponding inverse of 10 ns), the specific downsampling factor (having the smallest possible integral value greater than zero) is n=7. The effective clock rate therefore results at 0.1/7 GHz and the inverse of the effective clock rate at 70 ns. In this case, the slack would be +3 ns, which corresponds to a time surplus. At the same time, the inverse of the effective clock rate ascertained in this way (i.e., with the specific downsampling factor, which has the smallest possible integral value greater than zero) also corresponds to the minimum latency of the specific signal path, i.e., 70 ns in the present case.

Within the meaning of this application, a delay of a signal path is preferably understood to be a runtime of a data signal along the particular signal path, in particular from a beginning of the particular signal path to an end of the particular signal path, as a result of the logic calculations carried out along the particular signal path, this representing, in particular, a clock-independent examination of the runtime without taking registers into account.

Particularly in the case of a specific signal path (in particular, in which a timing error does not occur or no longer occurs during the timing analysis), the sum of delay V of the particular specific signal path and slack S of the particular signal path corresponds to minimum latency L of the particular signal path, L=V+S—for an effective clock rate given for the particular specific signal path and with a positive slack.

When it is mentioned in this application that an ascertainment of a value (of a variable such as the delay or the like) takes place at least implicitly, this means, for example, that the particular value does not have to be obtained as an intermediate result at any point in the method (which in this respect would represent an explicit ascertainment, which, however, is not ruled out). The value may also flow, for example, into a higher-level ascertainment (for example, within a closed expression), which then—implicitly—makes use of the value.

When it is therefore mentioned in this application that an ascertainment of a value (of a variable such as the specific downsampling factor) takes place implicitly, based on another value (of another variable), this means, for example, that the particular other value may occur within a larger expression (such as a formula) during the ascertainment of the one value, without having to appear as an independent value to the outside.

Alternatively or additionally, it may also be provided that at least one interface in the circuit design is assigned to the specific signal path, in particular, at least one I/O interface and/or a model interface, via which the specific signal path is connected or connectable on the input side to at least one third signal path, which is preferably clocked at a clock which is different from the base clock frequency, and/or whose signal value is provided to the specific signal path, preferably at a rate which is different from the base clock frequency, the specific downsampling factor being set to a downsampling factor stored in the definition of the interface.

The interface is advantageously also an input interface for the specific signal path. For this purpose, the specific signal path is data-linked to an output of the interface. The third signal path may be data-linked to the interface at an input of the interface.

For example, a converter may be provided for this purpose, for example an analog/digital converter (also referred to in short as an A/D converter), which converts the signal values of the third signal path, and which are then provided to the specific signal path at the aforementioned rate. The converter therefore supplies the converted values at a certain clock rate. The inverse of this rate is also referred to in the present application as a “pattern (of the converter/input signal/an interface, which may have, for example, the converter).” The converter may be part of the particular interface or form the interface. The converter may also alternatively be independent and/or formed as part of the third signal path and be provided upstream from the interface in the data flow (in this case, the converter is no longer necessarily part of the circuit design).

An interface preferably also generally has at least two connection sides (as in the present case). At least one first connection side is designed to be data-linked to a first signal path. At least one second connection side is designed to be data-linked to a second signal path. The interface may be data-linked, for example, to the third signal path on the first connection side (in particular, to the output of a converter assigned to the third signal path) and be data-linked to the specific signal path on the second connection side.

The effective clock rate for the particular specific signal path may be particularly easily set thereby. After all, it is sufficient to set the downsampling factor from the definition of the interface as the specific downsampling factor. The specific signal path may thus also be data-linked to signal paths (such as the third signal path) whose signal values are provided, in particular converted, at a clock rate which is different from the base clock frequency.

The third signal path may be part of the circuit design, or it may be a signal path independent thereof.

The circuit design may be data-linked via an I/O interface to signal paths situated outside the circuit design. In this case, the third signal path is not part of the circuit design.

A model interface may advantageously include a register or be formed thereby, for example, to receive parameters from a processor model.

The setting of the specific downsampling factor may take place manually or automatically in the circuit design. For example, the downsampling factor stored in the interface definition may be set as the specific downsampling factor by defining a signal path as a multi-cycle signal path. Alternatively or additionally, the specific downsampling factor may be at least partially set based on a result of a comparison of the negative slack of the specific signal path to the base clock frequency.

Alternatively or additionally, it may also be provided that the method includes the fact that each of at least two first specific signal paths in the circuit design to be mapped is defined as a multi-cycle path, each having the identical effective clock rate.

In this case, for example, at least two signal paths of the circuit design may be selected as the at least two first specific signal paths from among the signal paths of the circuit design to be mapped for which a timing error is detected during the timing analysis.

The identical effective clock rate may accordingly be set in the circuit design at least partially and/or at least implicitly based on an identical downsampling factor applied, in particular, to the base clock frequency.

The identical specific downsampling factor, which is thus the same in terms of numeric value, is then set for all specific signal paths.

The at least two first specific signal paths preferably have a common circuit design block, in particular, in the form of an output and/or input block, in the circuit design to be mapped.

The at least two first specific signal paths are preferably based on a common input block in the circuit design to be mapped. Alternatively or additionally, the at least two first specific signal paths run in the direction of different output blocks in the circuit design to be mapped.

The at least two first specific signal paths preferably emanate from two different input blocks in the circuit design to be mapped. Alternatively or additionally, the at least two first specific signal paths run in the direction of a common output block in the circuit design to be mapped.

Further specific signal blocks having the identical effective clock rate as the at least two first specific signal paths may exist, which, however, are not taken into account in the examination and are therefore not referred to as first specific signal paths.

To operate the individual first specific signal paths having an identical effective clock rate (i.e., to set the corresponding effective clock rate for the particular first specific signal paths), the identical specific downsampling factor is advantageously set for each of the first specific signal paths. For this purpose, a common identical specific downsampling factor may be set at a single point, which has an effect for all first specific signal paths (for example, in a common block, such as a downsampling block). At least two identical specific downsampling factors may be alternatively or additionally set at at least two points, which have an effect for the first specific signal paths independently of each other but in the same way (for example, in at least two blocks, such as two downsampling blocks).

Alternatively or additionally, it may also be provided that a different delay of a signal along the particular first specific signal path may be at least implicitly ascertained in each case for the at least two first specific signal paths, and the identical specific downsampling factor is set for the identical effective clock rate of the at least two first specific signal paths, at least partially and/or at least implicitly based on the base clock frequency and/or a delay corresponding to the maximum delay of the delays ascertained for the at least two first specific signal paths.

The effective clock rate for the at least two first specific signal paths may be particularly easily set thereby. The specific downsampling may then be ascertained based on the maximum delay among the first specific signal paths and the base clock frequency, which is generally known.

Reference may additionally be made to the to the preceding remarks on the delay, which entirely correspondingly apply here, unless otherwise apparent from the context.

Alternatively or additionally, it may also be provided that an, in particular integral, downsampling factor is at least implicitly defined for each of the at least two first specific signal paths, the particular downsampling factor describing in each case an, in particular integral, ratio of the base clock frequency and the inverse of the minimum latency of the particular specific signal path.

The smallest possible downsampling factor selected in relation to the particular delay may thus be defined for each of the first specific signal paths. During further measures, a correspondingly defined downsampling factor may therefore be employed for each first specific signal path, and, on this basis, for example, one or multiple specific downsampling factors may be ascertained and used to set the particular effective clock rate.

Alternatively or additionally, it may also be provided that at least one interface is assigned to the at least two first specific signal paths, in particular, at least one I/O interface and/or a model interface, via which the particular first specific signal path is connected to at least one third signal path on the output side, the third signal paths preferably each being clocked at clock rates which are different from the base clock frequency and are at least partially different from each other, and/or the third signal paths preferably expect, in each case, data at a rate which is different from the base clock frequency and rates which are at least partially different from each other; and an upsampling factor for the particular first specific signal path, to which the particular interface is assigned, being stored for each interface in an associated interface definition, and, for the identical effective clock rate of the at least two first specific signal paths, the identical specific downsampling factor being set to the value corresponding to the maximum value among all upsampling factors stored in the aforementioned interface definitions.

The interfaces are advantageously also each an output interface for the specific signal path.

The effective clock rate for the first specific signal paths may be particularly easily set thereby. It is sufficient to set the downsampling factor from the definitions of the interfaces having the highest value for all first specific signal paths as the identical specific downsampling factor. The first specific signal paths may thus also be data-linked to signal paths (such as the third signal paths) which expect data having a clock which is different from the base clock frequency.

The individual third signal paths may therefore be part of the circuit design, or they may be a signal paths independent thereof. The above remarks similarly apply with regard to the I/O interface and the model interface.

The at least two first specific signal paths can have a common input interface.

The setting of the specific downsampling factor may take place manually or automatically in the circuit design. For example, the largest of the downsampling factors stored in the associated interface definitions may be set as the specific downsampling factor by defining two signal paths as a multi-cycle signal paths. Alternatively or additionally, the specific downsampling factor may be at least partially set based on a result of a comparison of the largest slack in terms of absolute value of the first specific signal path having the base clock frequency.

Alternatively or additionally, it may also be provided that, in particular, if the ratio of the greatest delay among the at least two first specific signal paths and the smallest delay among the at least two first specific signal paths is no more than a limit value, for example, 1.3, the identical specific downsampling factor is set, for the identical effective clock rate of the at least two first specific signal paths, to a divisor, in particular the largest common divisor, of all upsampling factors stored in the definitions of the interfaces assigned to the at least two first specific signal paths.

In other words, it is therefore advantageous if the delays of the individual first specific signal paths are sufficiently similar, the largest among the upsampling factors specified for the first specific signal paths is not selected as the identical specific downsampling factor for the first specific signal paths, but rather a corresponding divisor of the specified upsampling factor.

In the other case (i.e., if the ratio is greater than the limit value), the identical specific downsampling factor can be set, for the at least two first specific signal paths, to the value corresponding to the highest value among all upsampling factors stored in the aforementioned interface definitions, similarly to what has been described above.

For example, the limit value may be defined in advance.

In addition to the delay, however, other variables of the at least two first specific signal paths may also be set, which are, in particular, directly or indirectly associated with the delay and which are used for a decision as to whether an identical effective clock rate of the at least two first specific signal paths is set to a divisor. The largest and smallest upsampling factors of the individual first specific signal paths stored in the interface definitions may also be compared to each other instead of the delays.

Alternatively or additionally, it may be particularly advantageously provided that, if, for each specific signal path, the inverse of the clock rate resulting with the downsampling factor, which corresponds to the upsampling factor stored for the particular first specific signal path in the interface definition of this assigned interface is more than 1.3 times the minimum latency and/or delay of the particular specific signal path, the identical specific downsampling factor is set, for the identical effective clock rate of the at least two first specific signal paths, to a divisor, in particular the largest common divisor, of all upsampling factors stored in the aforementioned interface definitions. In other words, a clock rate f_{clock,i} = f_{base}/nᵢ may be ascertained (with base clock frequency f_{base}) for each first specific signal path, using upsampling factor nᵢ specified in its interface definition (of the output interface). It may then be checked for each first specific signal path whether the inverse of its clock rate determined in this way is more than 1.3 times its minimum latency and/or delay. If this condition is met for each first specific signal path (i.e., the inverse of this particular clock rate is more than 1.3 times the minimum latency and/or delay of the particular first specific signal path in each case), not the greatest among the upsampling factors specified for the first specific signal paths is selected as the identical specific downsampling factor for the first specific signal paths, but rather a corresponding divisor of the specified upsampling factors. In the other case (i.e., if not each of the first specific signal paths satisfies the comparison), the identical specific downsampling factor can be set, for the at least two first specific signal paths, to the value corresponding to the highest value among all upsampling factors stored in the aforementioned interface definitions.

Alternatively or additionally, it may also be provided that at least one interfaces is assigned to the at least two first specific signal paths, in particular, at least one I/O interface and/or a model interface, via which the particularly first specific signal path is connected to at least one third signal path on the output side, the third signal paths preferably each being clocked at clocks which are different from the base clock frequency and are at least partially different from each other, and/or the third signal paths preferably provide, in each case, data at a rate which is different from the base clock frequency and rates which are at least partially different from each other (in particular at the particular interface);

- a downsampling factor for the particular first specific signal path, to which the particular interface is assigned, being stored for each interface in an associated interface definition, and, for the identical effective clock rate of the at least two first specific signal paths, the identical specific downsampling factor being set to the value corresponding to the highest value among all downsampling factors stored in the aforementioned interface definitions.

The interfaces are advantageously also each an input interface for the particular specific signal path.

The effective clock rate for the first specific signal paths may be particularly easily set thereby. It is sufficient to set the downsampling factor from the definitions of the interfaces having the highest value for all first specific signal paths as the identical specific downsampling factor. The first specific signal paths may thus also be data-linked to signal paths (such as the third signal paths) which provide data having a clock which is different from the base clock frequency.

The individual third signal paths may therefore each be part of the circuit design, or they may be a signal paths independent thereof. The above remarks similarly apply with regard to the I/O interface and the model interface.

The at least two first specific signal paths can have a common output interface.

The setting of the specific downsampling factor may take place manually or automatically in the circuit design. For example, the largest of the downsampling factors stored in the associated interface definitions may be set as the specific downsampling factor by defining two signal paths as a multi-cycle signal paths. Alternatively or additionally, the specific downsampling factor may be at least partially set based on a result of a comparison of the largest slack in terms of absolute value of the first specific signal path having the base clock frequency.

Alternatively or additionally, it may also be provided that, in particular, if the ratio of the greatest delay among the at least two first specific signal paths and the smallest delay among the at least two first specific signal paths is no more than a limit value, for example, 1.3, the identical specific downsampling factor is set, for the identical effective clock rate of the at least two first specific signal paths, to a divisor, in particular the largest common divisor, of all downsampling factors stored in the definitions of the interfaces assigned to the at least two first specific signal paths.

In other words, it is therefore advantageous if the delays of the individual first specific signal paths are sufficiently similar, the largest among the downsampling factors specified for the first specific signal paths is not selected as the identical specific downsampling factor for the first specific signal paths, but rather a corresponding divisor of the specified downsampling factor.

In the other case (i.e., if the ratio is higher than the limit value), the identical specific downsampling factor can be set, for the at least two first specific signal paths, to the value corresponding to the highest value among all downsampling factors stored in the aforementioned interface definitions, similarly to what has been described above.

For example, the limit value may be defined in advance.

In addition to the delay, however, other variables of the at least two first specific signal paths may also be set in examples, which are, in particular, directly or indirectly associated with the delay and which are used for a decision as to whether an identical effective clock rate of the at least two first specific signal paths is set to a divisor. The largest and smallest downsampling factors of the individual first specific signal paths stored in the interface definitions may thus also be compared with each other instead of the delays.

Alternatively or additionally, it may be particularly advantageously provided that, if, for each of the specific signal paths, the inverse of the clock rate resulting with the downsampling factor stored for the particular first specific signal path in the interface definition of this assigned interface is more than 1.3 times the minimum latency and/or delay of the particular specific signal path, the identical specific downsampling factor is set, for the identical effective clock rate of the at least two first specific signal paths, to a divisor, in particular the largest common divisor, of all downsampling factors stored in the aforementioned interface definitions. In other words, a clock rate f_{clock,i} = f_{base}/nᵢ may be ascertained (with base clock frequency f_{base}) for each first specific signal path, using downsampling factor nᵢ specified in its interface definition (of the input interface). It may then be checked for each first specific signal path whether the inverse of its clock rate determined in this way is more than 1.3 times its minimum latency and/or delay. If this condition is met for each first specific signal path (i.e., the inverse of this particular clock rate is more than 1.3 times the minimum latency and/or delay of the particular first specific signal path in each case), not the largest among the downsampling factors specified for the first specific signal paths is selected as the identical specific downsampling factor for the first specific signal paths, but rather a corresponding divisor of the specified downsampling factors. In the other case (i.e., if not each of the first specific signal paths satisfies the comparison), the identical specific downsampling factor can be set, for the at least two first specific signal paths, to the value corresponding to the highest value among all downsampling factors stored in the aforementioned interface definitions.

Alternatively or additionally, it may also be provided that (i) if the relative and/or absolute difference between the largest and the smallest downsampling factor of the first specific signal paths is within a defined value range, and/or if at least one, preferably all, of the downsampling factors of the first specific signal paths is at least greater than one in each case, the at least two first specific signal paths are each defined as a multi-cycle path, each having the identical effective clock rate, and/or (ii) if the relative and/or absolute difference between the largest and the smallest downsampling factor of the first specific signal paths is outside the defined value range, and/or if at least one of the downsampling factors is one, at least one, preferably all, of the at least two first specific signal paths is defined in each case as a multi-cycle path, each having an effecting clock rate based in each case on a specific downsampling factor defined for the particular first specific signal path.

This makes it possible to advantageously control how great the difference should be between the individual downsampling factors defined for the individual first specific signal paths or predefined in an interface definition so that an identical specific downsampling factor is selected for the first specific signal paths. Alternatively or additionally, it may correspondingly also be defined as a prerequisite that at least one of the first specific signal paths undergoes an increase in the sense of a reduction of its latency by the downsampling (implied by a specific downsampling factor defined for the particular first specific signal path and having a value greater than one).

Otherwise, the particular specific downsampling factor for one of multiple of the first specific signal paths may in each case, in a departure therefrom, be set to the downsampling factor of the particular first specific signal path for the effective clock rate thereof. Alternatively or additionally, it may correspondingly also be defined as a prerequisite that the particular first specific signal path does not undergo an increase in the sense of a reduction of its latency by the downsampling using the identical specific downsampling factor. In any case, the first specific signal paths, which are each defined with an effective clock rate based on a specific downsampling factor according to the downsampling factor of the particular first specific signal path and/or in a departure from the identical specific downsampling factor, the ones having the largest downsampling factor, the smallest downsampling factor, and/or a downsampling factor having the value one may be advantageous.

Unless the opposite is apparent from the particular context, what is meant by the phrase “...downsampling factor of the specific signal path...” is preferably the downsampling factor defined in relation to the particular specific signal path and/or stored in a definition of an interface assigned to the particular specific signal path, which, according to the above remarks, does not absolutely have to correspond to the specific downsampling factor with which the effective clock rate of the particular specific signal path is set.

Alternatively or additionally, it may also be provided that, in case (ii) described above, the definition of the multi-cycle paths includes the fact that an additional downsampling block is assigned to the particular first specific signal path in the circuit design and/or is designed as part of an already existing block, and the downsampling factor of the particular first specific signal path is preferably stored in the downsampling block.

This is particularly advantageous in order to set, for at least one first specific signal path, an effective clock rate which deviates from at least one other first specific signal path.

The suitable downsampling factor may be assigned thereby to the first specific signal path not clocked at the identical effected clock rate.

When it is mentioned that a block (for example, the aforementioned downsampling block) is designed as part of an already existing block, this may mean, for example, that the functionality of the block (for example, a downsampling) is mapped in the already existing block. By adapting the already existing block in the circuit design, the same effect may thus be achieved with the additional block as with the already existing block (without adaptation).

Alternatively or additionally, it may also be provided that the at least two first specific signal paths are ascertained in that an associated input block in the circuit design to be mapped is ascertained for an identified first first specific signal path, and at least one further signal path, in particular a specific signal path, emanating from the ascertained input block and running in parallel in terms of signaling to the first first specific signal path, at least in sections, is ascertained and identified as the second first specific signal path.

In other words, a first first specific signal path is identified and its input block is ascertained. In addition to the first first specific signal path, (at least) one further specific signal path (running data-technologically in parallel to the first specific signal path, at least in sections) also emanates from this block and is then identified as the second first specific signal path.

Two specific signal paths running in parallel are thus clocked at an identical effective clock rate to the extent that, at least in examples, one of the conditions described above is met or nothing stands in the way of one of the conditions described above.

Alternatively or additionally, it may also be provided that an, in particular integral, downsampling factor is at least implicitly defined for at least one, preferably for at least two and/or all of the first specific signal paths, the particular downsampling factor describing in each case an, in particular integral, ratio between the base clock frequency and the inverse of the minimum latency of the particular specific signal path,

and/or

- in relation to at least one, preferably in relation to all, of the specific signal paths, the definition of the particular specific signal path as a multi-cycle path includes in each case the fact that at least two circuit design blocks assigned to the particular specific signal path are provided within the circuit design, with the aid of which the clock rate for the particular specific signal path is set to the effective clock rate;

- a first circuit design block of the at least two circuit design blocks in each case is preferably a downsampling block of the particular specific signal path in the circuit design and/or has its functionality, and/or the particular downsampling factor is stored in the first circuit design block, and/or a second circuit design block of the at least two circuit design blocks is an upsampling block of the particular specific signal path in the circuit design and/or has its functionality, and/or an upsampling factor corresponding to the particular downsampling factor is stored in the second circuit design block.

At least two of the specific signal paths can have at least one common circuit design block, for example a common input circuit design block.

The smallest possible downsampling factor selected in relation to the particular delay may be defined in each case for specific signal paths (of the same type, which do not necessarily have to be, for example, first specific signal paths). During further measures, a correspondingly defined downsampling factor may therefore be employed for each specific signal path, and, on this basis, one or multiple specific downsampling factors may be ascertained and used to set the particular effective clock rate. The downsampling factor defined here based on the minimum latency of the first specific signal path may, in a further case described farther below, be advantageously used as the specific downsampling factor instead of a downsampling factor specified in an interface definition, which will be discussed in greater detail later on.

In that corresponding circuit design blocks are provided, the effective clock rate may be particularly easily and reliably set for the particular specific signal path.

The first circuit design block is preferably situated in each case at the beginning of the particular specific signal path, in particular before the logic calculations. The second circuit design block is preferably situated in each case at the end of the particular specific signal path, in particular after the logic calculations.

In particular, the values of the downsampling factor of the specific signal path and the upsampling factor of the specific signal path each match each other in a specific signal path, in particular in a specific signal to which corresponding first and second circuit design blocks are assigned.

Within the meaning of this application, a (specific) downsampling factor is preferably understood to be a value which describes a ratio of the base clock frequency to an (effective) clock rate. In other words, the (effective) clock rate is obtained in that the base clock frequency is divided by the downsampling factor. Despite the division, the downsampling factor is referred to as a “factor.”

Within the meaning of this application, a (specific) upsampling factor is preferably understood to be a value which describes a ratio of a clock of a third signal path and the (effective) clock rate) (or alternatively a ratio of an inverse of a pattern of the third signal path (or an associated interface) and the (effective) clock rate). In other words, the clock of the third signal path or the inverse of the pattern of the third signal path (or an associated interface) is obtained in that the (effective) clock rate is multiplied by the upsampling factor. The aforementioned interface may be, for example, an interface with the aid of which an examined specific signal path is data-linked to the particular third signal path on its output-side end.

Alternatively or additionally, it may also be provided that, in at least one, preferably in at least two, and/or in all, of the specific signal paths, the first circuit design block is in each case an input FPGA interface block of the particular specific signal path in the circuit design to be mapped, by means of which the input-side interface of the particular specific signal path is preferably provided, and/or the second circuit design block is in each case an output FPGA interface block of the particular specific signal path in the circuit design to be mapped, by means of which the output-side interface of the particular specific signal path is preferably provided.

An FPGA interface block is a circuit design block for exchanging data, for example between the processor and FPGA, which includes at least one register. Examples of FPGA interface blocks are an input FPGA interface block at the beginning of a signal path (which may thus represent an input block of the particular signal path) and an output FPGA interface block at the end of a signal path (which may thus represent an output block of the particular signal path). For example, with respect to the signal flow in the signal path, a downsampling block may be provided after an input FPGA interface block, and an upsampling block may be provided before an output FPGA interface block.

A specific signal path may therefore be particularly easily defined as a multi-cycle path in the circuit design. For this purpose, it is sufficient, namely advantageous, to provide the particular input or output FPGA interface block in a specific signal path to be able to set the effective clock rate accordingly.

It may also be provided that a downsampling factor may be optionally defined in an input FPGA interface block, and in the case of a defined downsampling factor, the specific signal path to which the particular input FPGA interface block is assigned is defined as a multi-cycle path and clocked at the effective clock rate. To a certain extent, the specific signal path may be very easily defined thereby as a multi-cycle path, since, for example, only the specification of the downsampling factor, in particular the specification of a downsampling factor other than one, may be necessary therefor in the particular input FPGA interface block.

It may also be provided that an upsampling factor may be optionally defined in an output FPGA interface block, and in the case of a defined upsampling factor, the specific signal path to which the particular output FPGA interface block is assigned is defined as a multi-cycle path and clocked at the effective clock rate. To a certain extent, the specific signal path may be very easily defined thereby as a multi-cycle path, since, for example, only the specification of the upsampling factor, in particular the specification of a upsampling factor other than one, is necessary therefor in the particular output FPGA interface block.

Alternatively or additionally, it may also be provided that the at least two first specific signal paths, which are each defined as a multi-cycle signal path having the identical effective clock rate, (i) emanate from a common circuit design block, which is or includes the at least one downsampling block and/or has its functionality, and, in particular, the common circuit design block is a common input FPGA interface block, and/or a downsampling factor is stored in the common circuit design bock, which is set as the specific downsampling factor, and (ii) which run in the direction of different circuit design blocks of the circuit design, which each are or include at least one upsampling block and/or having its functionality, of which at least one, in particular all, is preferably an output FPGA interface block of the particular first specific signal path.

In other words, the at least two first specific signal paths may run from a common downsampling block (or input FPGA interface block having a block of this type or its functionality) to different upsampling blocks (or at least, in part, output FPGA interface blocks having an upsampling block of this type or its functionality).

Alternatively or additionally, it may also be provided that the carrying out or optimization includes a reduction of a latency and/or a slack, in particular in terms of absolute value, of the at least one specific signal path of the circuit design to be mapped in an FPGA.

This permits a particularly advantageous effect of the method.

The slack is preferably adapted by the optimization in the direction of zero and/or has a value greater than zero after the optimization.

Alternatively or additionally, it may also be provided that at least one interface, in particular an I/O interface and/or a model interface in the circuit design is assigned to at least one second specific signal path, which is preferably identical to one of the specific signal paths described above, in particular to one of he at least one first specific signal paths, and the specific downsampling factor is set in the circuit design at least partially and/or at least implicitly depending on at least one characteristic value of an external input signal present at or applicable to the interface, the specific downsampling factor preferably being stored in a definition of the interface.

The at least one second specific signal path is preferably thus identical to at least one of the at least one specific signal paths described above (in particular, identical to at least one of the at least one first specific signal paths described above).

Reference is generally made to the at least one specific signal path whose specific downsampling factor is set based on the characteristic value as the second specific signal path. However, further specific signal paths may exist, whose specific downsampling factor is also set in each case based on the same or another characteristic value, which are, however, not taken into account in the examination and are therefore not referred to as second specific signal paths.

The interface may advantageously be one of the interfaces described farther above.

It is understood that the input signal is not already present during the drafting stage of the circuit design and during the build. The input signal is not present at the correspondingly configured FPGA until runtime.

Alternatively or additionally, it may also be provided that the characteristic value is a pattern of the input signal and/or a measure of a jitter of the input signal, such as a delay of the input signal caused by the jitter.

The pattern of the input signal corresponds, for example, to the periodic time with which the directly consecutive values of the input signal are provided to the second specific signal path at the interface. In this respect, a conversion duration of an A/D converter may, for example, determine the pattern of the input signal. The pattern may therefore likewise be related to the converter or the associated interface (which may include the converter). In this regard, reference may also be made to the remarks farther above. In this application, however, the formulation “pattern of the input signal” is used for better readability.

With the aid of the pattern as a characteristic value, a triggering may advantageously take place in response to a clock rate of the external signal.

Jitter of the input signal is understood to be, for example, a constant or time-dependent (for example, positive or negative) shift in the input values provided at the interface with respect to the base clock frequency.

Influences acting upon the input signal may be advantageously taken into account with the aid of the jitter as a characteristic value.

Alternatively or additionally, it may be provided that, if in at least one of the specific signal paths, in particular, in at least one of the first specific signal paths, (i) the effective clock rate selected for the particular specific signal path, in particular as described above, results in a timing error in the particular specific signal path at runtime, due to the jitter, and/or (ii) the amount of the jitter is outside a defined permissibility range, the particular at least one specific signal path is treated as the at least one second specific signal path, and: the specific downsampling factor selected for the effective clock rate of the particular specific signal path is set to a smaller value, the reduction of the specific downsampling factor taking place at least partially based on the amount of the jitter, and/or the specific downsampling factor selected for the effective clock rate of the particular specific signal path is set in such a way that the inverse of the effective clock rate has a smaller value than the pattern.

A specific downsampling factor may first be advantageously set thereby for the effective clock rate of a specific signal path (which may be, in particular, a first specific signal path), as described farther above, and this specific downsampling factor may be adapted once again, taking the jitter into account, if at least one of the aforementioned criteria is met. The characteristic value (in the form of the jitter) of the input signal is taken into account thereby for the particular specific signal path during the selection of the specific downsampling factor. Reference is then made in terms of language to this specific signal path as the second specific signal path.

Alternatively or additionally, it may also be provided that a minimum latency of the at least one second specific signal path is ascertained, and the specific downsampling factor is set for the effective clock rate of the second specific signal path, also depending on the ascertained minimum latency.

In this respect, the specific downsampling factor is thus set at least based on the characteristic value of the input signal and the minimum latency.

Alternatively or additionally, it may also be provided that the specific downsampling factor is set for the effective clock rate of the second specific signal path in such a way that the inverse of the effective clock rate is identical to the pattern of the input signal, in particular if the ascertained minimum latency and/or delay of the second specific signal path is less than or equal to the pattern of the input signal.

The second specific signal path may by clocked thereby synchronously with the third signal path. A latency advantage may be used particularly well thereby.

Alternatively or additionally, it may also be provided that the specific downsampling factor is set for the effective clock rate of the second specific signal path in such a way that the inverse of the effective clock rate is greater than the ascertained minimum latency and/or delay of the second specific signal path, in particular if the ascertained minimum latency and/or delay of the second specific signal path is less than or equal to the pattern of the input signal.

This ensures that the logic calculations of the second specific signal path may be executed within the periodic time of the effective clock rate.

Alternatively or additionally, it may be provided that, in particular, (i) if the ascertained minimum latency and/or delay of the second specific signal path is greater than the pattern of the input signal, and/or (ii) if the downsampling factor stored in the interface definition is smaller than the downsampling factor defined for the second specific signal path based on the minimum latency of the second specific signal path (in particular, as described farther above),

the second specific signal path in the circuit design is divided into at least two partial signal paths, each having a minimum latency and/or delay which is smaller than the pattern, in particular due to a provision of at least one additional register assigned to the second specific signal path in the circuit design, and the specific downsampling factor is set for the effective clock rate of the second specific signal path in such a way that the inverse of the effective clock rate is (a) identical to the pattern, (b) is greater than or equal to the minimal latency and/or delay of the partial signal path having the greatest minimum latency and/or the greatest delay among the partial signal paths, and/or (c) is smaller than the ascertained minimal latency of the second specific signal path.

In that the second specific signal path is divided accordingly into multiple partial signal paths, the minimum latency and/or delay of each partial path may be advantageously reduced to the extent that it is below a certain limit (for example, the pattern of the input signal) in each case (or is not greater than this limit). The second specific signal path may be advantageously clocked thereby at an effective clock rate according to the inverse of the pattern of the input signal, even if its minimum latency is greater than the pattern.

Different measures may thus be carried out for the second specific signal path and/or with regard to its effective clock rate, depending on whether the minimum latency or the delay is larger than, smaller than, or equal to the pattern.

It should be noted, in particular, for the case (ii) just described that the second specific signal path in this case preferably corresponds to a first specific signal path, for which a downsampling factor was defined according to the minimum latency of the second specific signal path.

Alternatively or additionally, it may also be provided that the circuit design to be mapped is converted into an optimized circuit design to be mapped by defining the at least one multi-cycle signal path.

Alternatively or additionally, it may also be provided that the effective clock rate is provided in the form of a clock-based chip enable signal and/or a separate clock frequency.

According to a second aspect, the object is achieved by the invention in that software for generating a circuit design to be mapped in an FPGA is proposed, the software being configured to carry out a method according to the first aspect of the invention.

All advantages described in reference to the method according to the first aspect of the invention also apply correspondingly to the software according to the second aspect of the invention. Reference may therefore be made at this point to the previous remarks.

The features described in relation to the method according to the first aspect of the invention may also be provided correspondingly in the case of the software, individually and in any combination, unless otherwise apparent from the context.

For example, the software may be designed as a computer program product, which may be stored, in particular, in a non-volatile data memory. According to a further aspect, the object may therefore be achieved by the invention in that a computer program product is proposed, which comprises commands, which, when the program is executed by a device for processing data, prompt the latter to carry out a method according to the first aspect of the invention.

According to a third aspect, the object is achieved by the invention in that a device for processing data is proposed, which is configured to carry out a method according to the first aspect of the invention and/or to execute software according to the second aspect of the invention.

All advantages described in reference to the method according to the first aspect of the invention also apply correspondingly to the device according to the third aspect of the invention. Reference may therefore be made at this point to the previous remarks.

The features described in relation to the method according to the first aspect of the invention may also be provided correspondingly in the case of the device, individually and in any combination, unless otherwise apparent from the context.

According to a fourth aspect, the object is achieved by the invention in that an input FPGA interface block is proposed for software for generating a circuit design to be mapped in an FPGA, in particular for software according to the second aspect of the invention, the input FPGA interface block being designed to at least partially effectuate the fact that, when it is inserted into the circuit design to be mapped and its output side is associated with a signal path of the circuit design, the signal path is subsequently clocked at an effective clock rate, at least in sections, which is lower than a base clock frequency at which the signal path would be clocked as standard according to the circuit design to be mapped, the input FPGA interface block preferably at least partially causing an optimization to be carried out according to a method according to the first aspect of the invention.

A signal path may be particularly easily defined thereby as a multi-cycle path. The association may represent or include, for example, an establishment of a data link between an output side of the block and the signal path.

All advantages described in reference to the method according to the first aspect of the invention also apply correspondingly to the block according to the fourth aspect of the invention. Reference may therefore be made at this point to the previous remarks.

Alternatively or additionally, it may also be provided that the effective clock rate is set in the circuit design at least partially and/or at least implicitly based on (i) at least one downsampling factor stored in the input FPGA interface block and applicable, in particular, to the base clock frequency, and/or (ii) a clock of a signal present at or applicable to the input side of the block.

According to a fifth aspect, the object is achieved by the invention in that an output FPGA interface block is proposed for software for generating a circuit design to be mapped in an FPGA, in particular for software according to the second aspect of the invention, the output FPGA interface block being designed to at least partially effectuate the fact that, when it is inserted into the circuit design to be mapped and its input side is associated with a signal path of the circuit design, the signal path is subsequently clocked at an effective clock rate, at least in sections, which is lower than a base clock frequency at which the signal path would be clocked as standard according to the circuit design to be mapped, the output FPGA interface block preferably at least partially causing an optimization to be carried out according to a method according to the first aspect of the invention.

A signal path may be particularly easily defined thereby as a multi-cycle path. The association may represent or include, for example, an establishment of a data link between an input side of the block and the signal path.

An FPGA interface block according to the fourth aspect of the invention and an FPGA interface block according to the fifth aspect of the invention are advantageously associated with the same signal path. For example, the signal path may be associated in each case with one of the two blocks at its two ends.

All advantages described in reference to the method according to the first aspect of the invention also apply correspondingly to the block according to the fifth aspect of the invention. Reference may therefore be made at this point to the previous remarks.

Alternatively or additionally, it may also be provided that the effective clock rate is set in the circuit design at least partially and/or at least implicitly based on (i) at least one upsampling factor stored in the output FPGA interface block, and/or (ii) a clock of a signal present at or applicable to the output side of the block.

According to a sixth aspect, the object is achieved by the invention in that a circuit design to be mapped in an FPGA is proposed, which was at least partially optimized with the aid of a method according to the first aspect of the invention and/or was at least partially generated with the aid of software according to the second aspect of the invention, and/or includes at least one signal path whose first end is associated with an input FPGA interface block according to the fourth aspect of the invention, and/or whose second end is associated with an output FPGA interface block according to the fifth aspect of the invention.

In this way, the advantages described in reference to the method according to the first aspect of the invention may be achieved for one or multiple signal path(s) of the circuit design. Reference may therefore be made at this point to the previous remarks.

Alternatively or additionally, it may also be provided that the FPGA interface blocks cause an optimization to be carried out according to a method according to the first aspect of the invention, and/or the FPGA interface blocks being at least part of an optimization according to a method according to the first aspect of the invention.

According to a seventh aspect, the object is achieved by the invention in that an FPGA having a circuit design mapped therein is proposed, which is at least partially optimized with the aid of a method according to the first aspect of the invention and/or with the aid of software according to the second aspect of the invention.

In this way, the advantages described in reference to the method according to the first aspect of the invention may be achieved for an FPGA. Reference may therefore be made at this point to the previous remarks.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a shows a schematic representation of a part of a circuit design to be mapped in an FPGA;

FIG. 1b shows, in reference to the circuit design from FIG. 1a, a diagram having schematic time response of a base clock frequency illustrated therein, including illustrated execution times of logic calculations according to the prior art;

FIG. 1c shows a schematic representation of the circuit design from FIG. 1a, including a signal path highlighted based on an induced timing error;

FIG. 1d shows, in reference to the circuit design from FIG. 1a, multiple diagrams having schematic time responses of a base clock frequency and the effective clock rate illustrated therein, including illustrated execution times of logic calculations;

FIG. 2a shows a schematic representation of at least one part of a circuit design to be mapped in an FPGA;

FIG. 2b shows, in reference to the circuit design from FIG. 2a, multiple diagrams having schematic time responses illustrated therein;

FIG. 3a shows a schematic representation of at least one part of a circuit design to be mapped in an FPGA;

FIG. 3b shows, in reference to the circuit design from FIG. 3a, multiple diagrams having schematic time responses illustrated therein;

FIG. 3c shows multiple diagrams having schematic time responses illustrated therein for a further example and in reference to the circuit design from FIG. 3a;

FIG. 3d shows multiple diagrams having schematic time responses illustrated therein for a further example and in reference to the circuit design from FIG. 3a;

FIG. 4 shows a flowchart of a method according to the first aspect of the invention;

FIG. 5 shows software according to the second aspect of the invention;

FIG. 6a shows a device for processing data according to the third aspect of the invention;

FIG. 6b shows a schematic representation of a hardware-in-the-loop test environment;

FIG. 7a shows a schematic representation of an input FPGA interface block according to the fourth aspect of the invention;

FIG. 7b shows a schematic representation of an output FPGA interface block according to the fifth aspect of the invention;

FIG. 8 shows a circuit design to be mapped in an FPGA according to the sixth aspect of the invention; and

FIG. 9 shows an FPGA having a circuit design to be mapped therein according to the seventh aspect of the invention.

### DETAILED DESCRIPTION

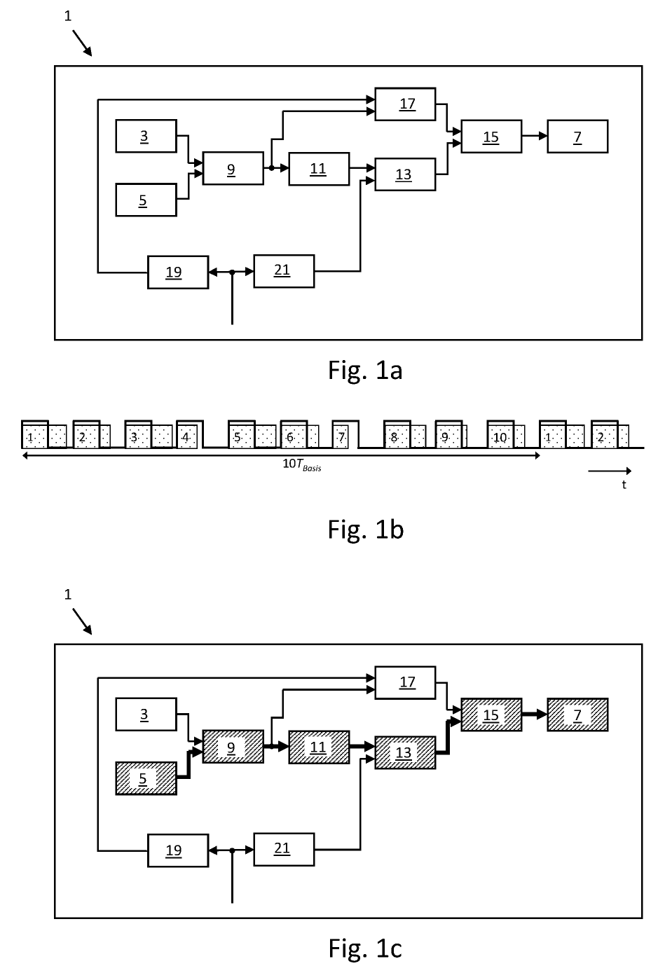

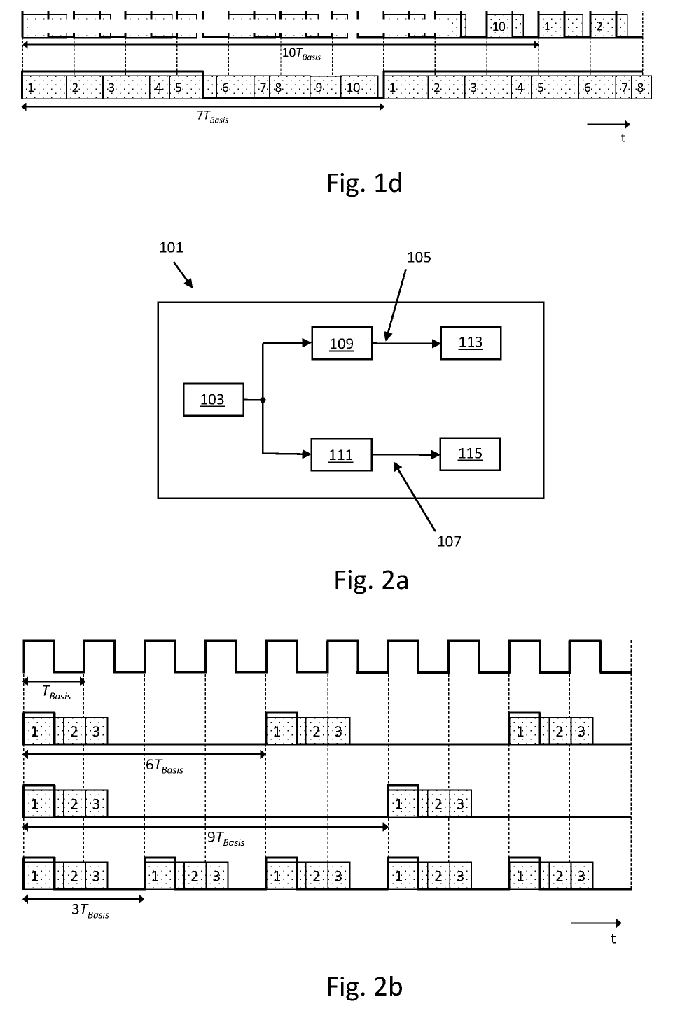

FIG. 1a shows a schematic representation of a part of a circuit design 1 to be mapped in an FPGA.

Circuit design 1 includes a circuit design block 3, a circuit design block 5, and a circuit design block 7. Circuit design blocks 3 and 5 each represent an input block in the form of an input FPGA interface block, and block 7 represents an output block in the form of an output FPGA interface block. In their characteristic as FPGA interface blocks, circuit design blocks 3, 5, and 7 provide interfaces to third signal paths outside circuit design 1. Corresponding input signals present in the FPGA in blocks 3 and 5 may be made available thereby in circuit design 1, where the data of the input signals provided via the interfaces are used. Correspondingly values may be transferred to an external third signal path via block 7. Signal paths, whose signal flow direction is apparent based on the arrows, run between input and output blocks 3, 5, 7. Different logic calculations, which are represented by circuit design blocks in the form of logic blocks 9, 11, 13, 15, and 17 of circuit design 1, are carried out in each case along the individual signal paths. For example, one signal path runs from input block 3 to output block 7 via logic blocks 9, 11, 13, and 15, and another signal path runs from input block 3 to output block 7 via logic blocks 9, 17, and 15. Likewise, one signal path runs from input block 5 to output block 7 via logic blocks 9, 11, 13, and 15, and another signal path runs from input block 5 to output block 7 via logic blocks 9, 17, and 15.

Internal signal paths may also be linked to third signal paths via corresponding interfaces, such as those of blocks 3, 5, and 7. Although the third signal paths were described in the present case as external signal paths, which are not part of circuit design 1, in specific embodiments the third signal paths may also be at least partially part of another model of the same circuit design 1. In this case, multiple different models comprised by circuit design 1 may be data-linked to each other via the interfaces.

A logic block, such as logic blocks 9, 11, 13, 15, and 17, carries out in each case logic calculations on input data present at its input and provides a result obtained thereby at its particular output. This result is then used, in turn, as input data for the block(s) following downstream (for example, a register or a further logic block). The logic calculations in each block require a certain execution time, which depends on the type of logic calculation. For example, an adder is implemented by block 9, which supplies the sum of the two values present at the input as the result at the output. An integrator, for example, is, in turn, implemented by block 11, which supplies an integration of the value present at the input as the result at the output. The different logics present among the two blocks 9 and 11 require different execution times. The adder of block 9 is generally executed faster than the integrator of block 11.

In addition to further circuit design blocks, which, however, are not illustrated in FIG. 1a, circuit design 1 also includes examples of exemplary circuit design blocks 19 and 21. The open end of the signal path running to blocks 19 and 21 may be data-linked, for example, to a part of the circuit design which is not illustrated in FIG. 1a.

It should be noted that, for the sake of clarity and due to the schematic nature of the representation of circuit design 1 in FIG. 1a, only examples of signal paths are at least partially illustrated as connecting lines between the individual blocks, and clock lines, in particular, are not sketched. The same also applies to all other representations of circuit designs.

Circuit design 1 is conceived of as a synchronous design and clocked at a base clock frequency predefined by an FPGA chip. In the present case, the base clock frequency may be, for example, f_{base} = 0.1 GHz, and the inverse thereof may correspondingly be T_{base} = 10 ns. In circuit design 1, a register is also provided for the interfaces in each of circuit design blocks 3, 5, and 7. A register may also be provided in each of logic blocks 9 through 17 so that the logic calculations may be carried out at a given base clock frequency along the signal paths. The registers of circuit design 1 are clocked at the base clock frequency. It is known per se to those skilled in the art that the logic calculation between two directly consecutive registers must be completed within one clock cycle in each case. In other words, the logic calculation between directly adjacent registered in the data system should not last longer than the inverse of the base clock frequency (including periodic time T_{base}).

If a logic calculation between two adjacent registers takes longer than the inverse of the base clock frequency, a started FPGA build aborts with a timing error, and at least one further register must be conventionally inserted into the relevant signal path, so that the logic calculation may be distributed to multiple clocks, so that under these circumstances the logic calculations carried out between adjacent registers are always completed within a time period according to the inverse of the base clock frequency.

The logic calculations along the signal path between input FPGA interface block 5 and output FPGA interface block 7 along logic blocks 9, 11, 13, and 15 are conventionally distributed, for example, to ten clocks of the base clock frequency, for which purpose a sufficient number of registers must be provided along the path. Minimum latency L along the signal path is thus 10 clocks of the base clock frequency, thus also L = 100 ns.

FIG. 1b shows, in reference to circuit design 1 from FIG. 1a, a diagram having a schematic time response of a base clock frequency illustrated therein, including illustrated execution times of logic calculations according to the prior art. Time axes t always run horizontally in the diagrams.

The execution times in which the logic calculations determined by lock blocks 9 through 15 take place are illustrated by boxes filled with dots. Each execution time 1 through 10 is shorter than the inverse of base clock frequency (periodic time T_{base}). In the present case, however, the pure calculation duration of the logic along the signal path, and thus also the runtime designated as delay V of a data signal along the signal path as a result of the logic calculations carried out along the signal path, is, for example, only V = 67 ns.

The difference between the minimum latency and delay of S = 33 ns in the present case, which is also referred to as slack, is attributed to the individual timing reserves in each clock. In other words, the sum of the timing reserves between consecutive registers in the signal path corresponds directly to slack S. The individual timing reserves may be different in the individual logic calculations, depending on their particular execution time. For example, the timing reserve in the first clock illustrated in FIG. 1b is smaller than in the fourth clock illustrated in FIG. 1b, since execution time 1 is longer than execution time 4.

To reduce the latency of the described signal path in circuit design 1, an optimization of the signal path may be carried out with the aid of a method according to the first aspect of the invention. For this purpose, circuit design 1 may be generated, for example, with the aid of software for generating a circuit design to be mapped in an FPGA according to the second aspect of the invention.

When a circuit design is initially modeled, the number of necessary registers may often not be reliably predicted, for which reason a register is inserted, for example, between each of the blocks illustrated in circuit design 1, and a timing analysis is subsequently carried out for circuit design 1. The timing analysis then ascertains, as already explained above, signal paths, in which calculations cannot be completed within the existing clock times. As a specific example, the delay explained above of V = 67 ns occurs on the signal path from interface block 5 to interface block 7 along circuit design blocks 9, 11, 13, and 15. If a timing analysis is now carried out for circuit design 1, a timing error is determined for this signal path as a result of the timing analysis, since the delay of the signal path is V = 67 ns, and the logic calculations between the five existing registers may not be carried out during a single periodic time of the base clock frequency of T_{base} = 10 ns. The relevant signal path must thus be optimized and may be illustrated, for example, in a correspondingly highlighted manner at the end of the timing analysis. Further pieces of information on the relevant signal path may also be optionally obtained as the result of the timing analysis. Examples thereof are the delay and the slack of the signal path.

It should be noted at this point that a removal of registers, like an addition of registers does not necessarily have to change anything in the schematic representation of circuit design 1 in FIG. 1a. The reason for this is that the registers are typically not shown on this examination level of circuit design 1. The registers are therefore “under the hood” of a circuit design block and therefore not illustrated separately in the circuit design, depending on the examination level of circuit design 1. The same may also apply, for example, to interface blocks which are typically provided as subsystems.

FIG. 1c shows for this purpose a schematic representation of the circuit design from FIG. 1a, in which the signal path to be optimized, including circuit design blocks 5 through 15 assigned to this signal path, is highlighted, as a result of the timing error. For example, the software for generating circuit design 1 may be correspondingly designed to generate a representation of this type and to output it on a screen.

The signal path which caused the timing error, which in the present case is only a single one, is selected as the specific signal path. An optimization is thus carried out for the specific signal path.

For this purpose, the specific signal path is defined in circuit design 1 to be mapped as a multi-cycle path having an effective clock rate f_{eff}. The effective clock rate is different from the base clock frequency and is set in circuit design 1 with the aid of a specific downsampling factor, which is applied to the base clock frequency. For this purpose, a chip enable signal controls, for example, the execution clock in the multi-cycle path accordingly in the practical implementation.

FIG. 1d shows, in reference to circuit design 1 from FIG. 1a, multiple diagrams having schematic time responses of a base clock frequency and the effective clock rate illustrated therein, including illustrated execution times of logic calculations.

The time response of the base clock frequency known from FIG. 1b is again illustrated in row 1 of FIG. 1d, including conventional execution times 1 through 10 of the logic calculations.

A specific downsampling factor of n=7 is set in the present case based on the delay of the specific signal path of V = 67 ns (which was obtained, for example, as the result of the timing analysis) and in light of the base clock frequency of f_{base} 0.1 GHz. The specific signal path is clocked thereby at an effective clock rate, which is currently f_{eff} = f_{base}/7. In turn, an inverse of the effective clock rate of T_{eff} = 7T_{base} = 70 ns thus results. This is greater than the delay of the specific signal path (V - 67 ns), so that all logic calculations along the specific signal path may be carried out within a single clock cycle of the effective clock rate, as is apparent based on the execution times 1 through 10 in the second row of FIG. 1d, by comparison with the profile of the effective clock rate, which is also sketched. Additional registers are therefore not necessary in the specific signal path. At the same time, the slack of the specific signal path (of 33 ns according to the prior art) is reduced to S = 3 ns. Above all, however, the latency is reduced from the previous 100 ns to L = 70 ns. Indeed, a timing reserve no longer has to be provided ten times for the specific signal path, which conventionally required ten clocks of the base clock frequency, but instead a timing reserve is required only a single time in the multi-cycle path, and it may be smaller than the sum of the previous timing reserves.

The specific downsampling factor of the specific signal path may be stored, for example, in a downsampling block assigned to the specific signal path. In parallel thereto, an upsampling factor corresponding to the downsampling factor for the specific signal path may advantageously also be stored in an upsampling block assigned to the specific signal path. The specific downsampling factor may optionally be set by means of the storage. The downsampling block is preferably provided at the beginning of the specific signal path and, in particular, designed as part of interface block 3. The upsampling block is preferably provided at the end of the specific signal path and, in particular, designed as part of interface block 7.

In that the specific signal path is consequently defined as a multi-cycle path in the circuit design to be mapped, the clock frequency for the specific signal path may be reduced by means of downsampling, and its latency L may thus be reduced as illustrated, taking into account the delay of the specific signal path and the base clock frequency.

It should be noted that, in the present specific embodiment, the clock on the specific path defined as a multi-cycle path is actually identical to the base clock frequency, while the registers of the specific signal path defined as a multi-cycle path are executed (“enabled”) only every nth clock frequency. The specific signal paths thus receive new input values only every nth clock and gain n times the time during a timing analysis. (The value of the downsampling factor set for the effective clock rate of the specific signal path is designated as n.) The representation of the effective clock rate in FIG. 1d and in further figures, which deviates therefrom, is therefore selected for reasons of improved understandability. In other specific embodiments, however, a different implementation may also be advantageously selected. For example, for at least one specific signal path defined as a multi-cycle path, which is to be clocked at a clock rate different from the base clock frequency, the effective clock rate thereof may be provided by a separate clock rate.

FIG. 2a shows a schematic representation of at least a part of a circuit design 101 to be mapped in an FPGA.

Circuit design 101 includes a circuit design block 103, which represents an input block in the form of an input FPGA interface block. Two signal paths 105 and 107 running data-technologically in parallel to each other emanate therefrom, along which different logic calculations are carried out in each case, which in combination are represented as logic block 109 and logic block 111 in circuit design 101. Each of signal paths 105, 107 is connected in a data-linked manner to a circuit design block 113 and 115, respectively, which each represent an output block in the form of an output FPGA interface block.

To reduce the latency of signal paths 105 and 107 in circuit design 101, an optimization of signal paths 105 and 107 may be carried out with the aid of a method according to the first aspect of the invention. Since signal paths 105 and 107 run data-technologically in parallel to each other in, an advantageously designed optimization may be carried out.

For this purpose, as described above in reference to circuit design 1, it is advantageous if at least signal paths 105 and 107 to be optimized do not contain any registers, or if the three registers of circuit design blocks 103, 113, and 115 are at most present.

At least the two signal paths 105 and 107 will cause a timing error during a timing analysis of circuit design 101 (provided that the delays along all signal paths 105 and 107 are each longer than the inverse of the base clock frequency). The two signal paths 105 and 107 are selected to carry out the optimization and are therefore again referred to as specific signal paths. Since the two signal paths run data-technologically in parallel to each other, they are referred to more specifically as first specific signal paths.

In the present case, signal paths 105, 107 running data-technologically in parallel to each other and, in this respect, to be optimized together, may be determined manually, for example by a person who is designing circuit design 101. Alternatively or additionally, signal paths 105 and 107 running in parallel to each other may also be ascertained as follows, for example: At least one or each first specific signal path having a received timing error may be tracked from the associated output FPGA interface block (in this case, circuit design blocks 113 and 115) to the associated input block in the form of the input FPGA interface block (in this case, circuit design block 103); all signal paths emanating from this input FPGA interface block are ascertained by the input FPGA interface block ascertained in this way. The first signal paths running data-technologically in parallel to each other (such as signal paths 15 and 107) may be ascertained thereby and optimized in groups in each case.

For each of first specific signal path 105 and 107, delay V₁ and V₂ thereof may be obtained as a result of the timing analysis. Based thereon, and taking into account the base clock frequency, the smallest possible integral downsampling factor n₁ and n₂ may then be defined for each signal path in such a way that particular delay Vᵢ is smaller than or equal to the inverse of f_{base}/nᵢ (where i=1 for specific signal path 105 and i=2 for specific signal path 107).

As mentioned above, the two first specific signal paths 105 and 107 identified as being data-technologically in parallel to each other are to be optimized. For this purpose, each of specific signal paths 105, 107 is defined as a multi-cycle path in circuit design 101 to be mapped, each having the identical effective clock rate. The identical effective clock rate is set with the aid of an identical specific downsampling factor, which is applied to the base clock frequency. For this purpose, downsampling factor nᵢ (i=1,2) having the largest value is selected, and it is then set as the specific downsampling factor.

Instead of first ascertaining a downsampling factor nᵢ for each first specific signal path, a downsampling factor may alternatively also be ascertained only for the first specific signal path which has the maximum delay Vᵢ (i=1.2), as described above, (for example, based on the timing analysis). The downsampling factor ascertained in this way may then be set directly as the specific downsampling factor for the effective clock rate of the two first specific signal paths 105, 107.

As described above in connection with circuit design 1, specific downsampling factor of first specific signal paths 105 and 107 may in this case also be stored in a (common) downsampling block, which is assigned to first specific signal paths 105 and 107 and may be part of circuit design block 103, and be optionally set thereby.

In parallel thereto, an upsampling factor corresponding to the specific downsampling factor may advantageously also be stored in each upsampling block assigned to first specific signal paths 105, 107. The downsampling block is preferably provided in a common beginning section of first specific signal path 105, 107 and, in particular, designed as part of interface block 103. The individual upsampling blocks are preferably provided at the end of particular first specific signal paths 105 and 107 and are each designed, in particular, as part of particular interface blocks 113 and 115.

In specific embodiments, upsampling factors may be already predefined in the interface definition for each of the two first specific signal paths 105 and 107. For example, an upsampling factor for particular first specific signal paths 105 and 107 may be stored for each output FPGA interface block 113, 115 in an associated interface definition. In this case, the upsampling factor having the largest value may be taken directly from the particular interface definition and be set as the specific downsampling factor.

A further optimization of the first specific signal paths 105, 107 running data-technologically in parallel to each other may advantageously take place in that the maximum delay and the minimum delay are ascertained for the first specific signal paths and the ratio formed. If the ratio is not greater than a limit value (for example, smaller than or equal to 1.3), the identical specific downsampling factor may be advantageously set to a divisor (for example, the largest common divisor) of all upsampling factors in the definitions of the interfaces assigned to the first specific signal paths. This may be particularly advantageous if, in specific embodiments, first specific signal paths 105, 107 are data-linked via FPGA interface blocks to different third signal paths, which have at least partially different inverse patterns deviating from the base clock frequency. This will be discussed in detail below. “Inverse pattern” in this case means the inverse of the pattern (of the particular third signal path or an associated interface), i.e., a clock rate.

For example, an upsampling factor n = 6 may be stored for first specific signal path 105, so that a downsampling factor of n = 6 results for first specific signal path 105, and an upsampling factor of n = 9 may be stored for second specific signal path 107, so that a downsampling factor of n = 9 results for second specific signal path 107.

FIG. 2b shows, for this case and in reference to circuit design 101 from FIG. 2a, multiple diagrams having schematic time responses illustrated therein.

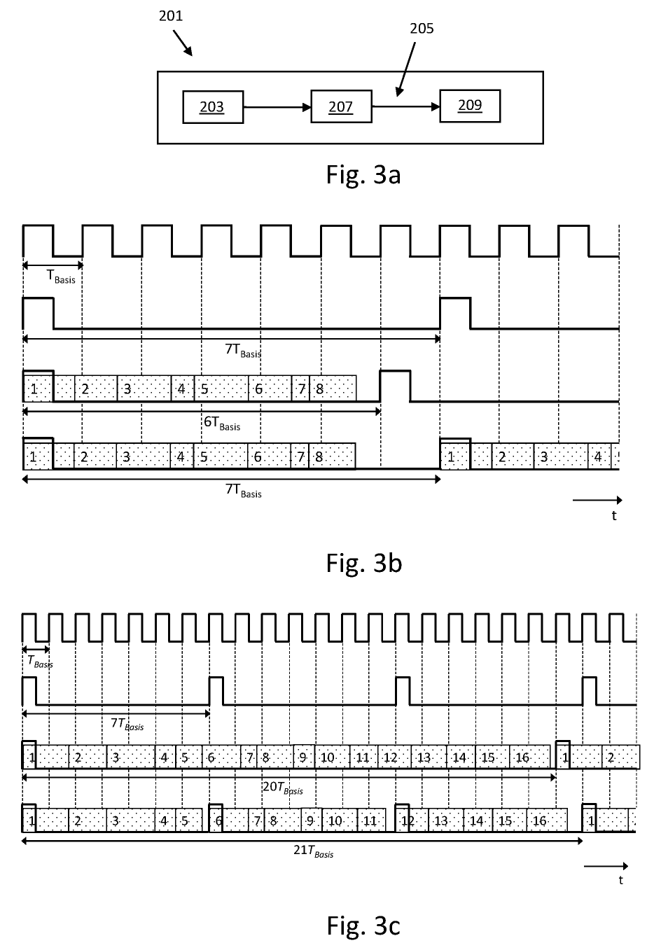

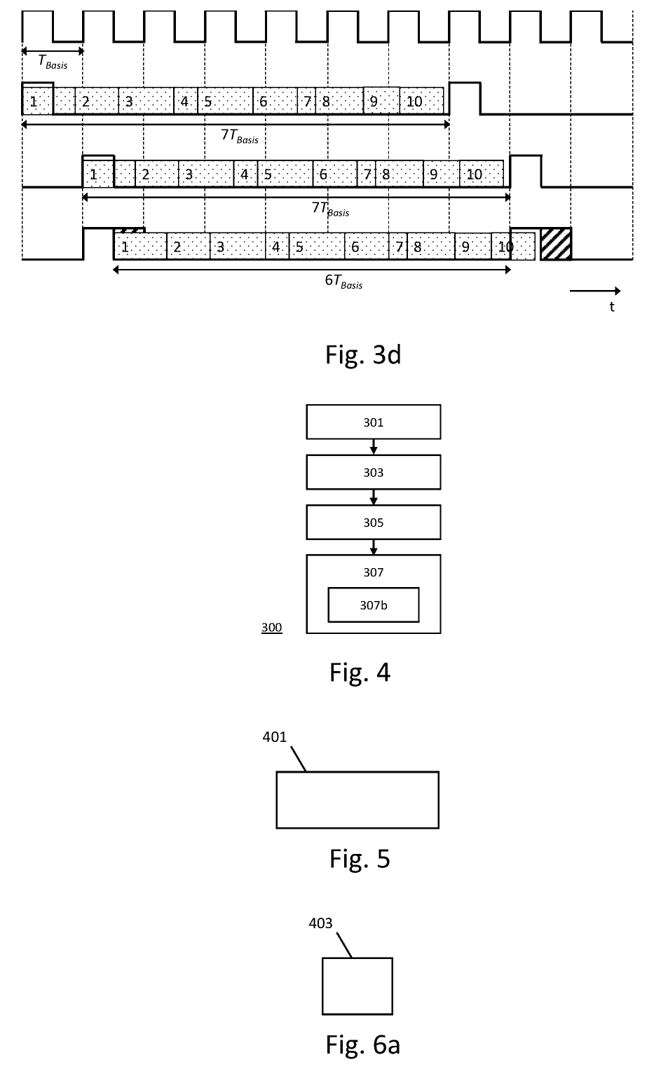

A time response of the base clock frequency is illustrated in row 1 of FIG. 2b. A time response of a clock rate is illustrated in each case in rows 2 and 3 of FIG. 2b, which, with the aid of particular downsampling factors, result in n = 6 for first specific signal path 105 and in n = 9 for first specific signal path 107. In addition to the clock rates, execution times of logic calculations 1 through 3 in blocks 111 and 113, respectively, are also each shown in rows 2 and 3. The ratio of the maximum and minimum delay in the two first specific signal paths 105, 107 is less than a limit value (for example, 1.3). During the definition of the two first specific signal paths 105, 107 as multi-cycle paths, the identical specific downsampling factor for the two first specific signal paths 105, 107 may therefore also be set to a divisor of the two downsampling factors. In the present case, the identical specific downsampling factor for the two first specific signal paths 105, 107 is set to the greatest common divisor (ggT), therefore also to n = ggT(6.9) = 3. A time response of the effective clock rate set in this manner is illustrated in row 4 of FIG. 3b, at which the two first specific signal paths 105, 107 are then clocked as multi-cycle paths in this example.

In that the specific signal paths are consequently defined as a multi-cycle path in the circuit design to be mapped, the clock frequency for the specific signal paths may be reduced in each case to an identical value by means of downsampling, and their latency may be advantageously reduced in each case, in particular, taking into account the delay of the specific signal path and the base clock frequency.

In specific embodiments, the two first specific signal paths 105 and 107 may be defined as multi-cycle paths having an identical effective clock rate only if the relative and/or absolute difference between the largest and the smallest downsampling factor of first specific signal paths 105 and 107 is within a defined value range, and/or if at least one, preferably all, of the downsampling factors of first specific signal paths 105 and 107 is/are each greater than one (i.e., at least one first specific signal path has a latency reduction due to the downsampling). Alternatively or additionally, if the relative and/or absolute difference between the largest and the smallest downsampling factor of first specific signal paths 105 and 107 is outside the defined value range, and/or if at least one of the downsampling factors is one, at least one, preferably all, of the at least two first specific signal paths 105 and 107 may each be defined as a multi-cycle path, each having an effective clock rate based on a specific downsampling factor according to particular first specific signal path 105 and 107. For this purpose, an additional downsampling block may be provided in each case in the at least one relevant first specific signal path, with the aid of which the downsampling factor may be defined as the specific downsampling factor for the first specific signal path. The rest of first specific signal paths 105 and 107 may then continue to be operated at an identical effective clock rate.

In specific embodiments, the decision may be made as to whether the at least two first specific signal paths 105 and 107 are defined as multi-cycle paths having an identical effective clock rate, also depending on whether or not a relative and/or absolute difference between the largest and the smallest delay of first specific signal paths 105 and 107 is within a defined value range (in this case, the identical effective clock rate is defined) instead of on the downsampling factor.

FIG. 3a shows a schematic representation of at least a part of a further circuit design 201 to be mapped in an FPGA.

Circuit design 201 includes a circuit design block 203, which represents an input block in the form of an input FPGA interface block. A signal path 205 emanates therefrom, along which different logic calculations are carried out, which in combination are represented as logic block 207. Signal path 205 is connected in a data-linked manner to a circuit design block 209, which represents an output block in the form of an output FPGA interface block.

Signal path 205 may be data-linked to third signal paths in each case via interface blocks 203, 209. New input values may be provided to signal path 205 via interface block 201 according to a pattern predefined by the third signal path (or the converter which converts the signal values of the input signal). The pattern is a periodic time with which new input data are provided.

To reduce the latency of signal path 205 in circuit design 201, an optimization of the signal path may be carried out with the aid of a method according to the first aspect of the invention.

For this purpose, it is again advantageous if at least signal path 205 to be optimized does not contain any registers, or at most the two registers of interface blocks 203 and 207.

A timing analysis is subsequently carried out for circuit design 1, and a timing error is obtained (at least) for signal path 205. Signal path 205 is selected for carrying out the optimization and is referred to as the second specific signal path.

However, the pattern may be different than the minimum latency of signal path 205, as in the present case.

For example, the input signal present at the interface of circuit design block 203 (and thus the interface of circuit design block 203) may have a pattern of 70 ns, i.e., it may provide a new value to second specific signal path 205 every 70 ns. Assuming that second specific signal path 205 has a minimum latency of 60 ns, it would be disadvantageous to operate second specific signal path 205 at an effective clock rate corresponding thereto (i.e., to execute it with its minimum latency every 60 ns). As a result, a new input value would under certain circumstances already be 60 ns old before it would be taken into account by the logic calculations (block 207) of second specific signal path 205. In this case, a result from second specific signal path 205 would then be obtained only after 130 ns (60 ns + 70 ns).

An advantageous optimization is thus carried out for the specific signal path. For this purpose, the second specific signal path is defined in the circuit design to be mapped as a multi-cycle path having an effective clock rate. The effective clock rate is set with the aid of an identical specific downsampling factor, which is applied to the base clock frequency.

The specific downsampling factor, and thus the effective clock rate, is in the present case set at least partially based on a characteristic value of the input signal, namely based on the pattern of the input signal. The pattern of the input signal is at least partially determined by a converter which converts the input signal.

If the minimum latency and/or delay (depending on which variable is considered) of second specific signal path 205 is smaller than or equal to the pattern of the input signal, the specific downsampling factor is set for second specific signal path 205 in such a way that the inverse of the effective clock rate is identical to the pattern of the input signal.

FIG. 3b shows, for this case and in reference to circuit design 201 from FIG. 3a, multiple diagrams having schematic time responses illustrated therein.

A time response of the base clock frequency is illustrated in row 1 of FIG. 3b, and a time response of the pattern of the input signal is illustrated in row 2 of FIG. 3b. A time response of a clock rate is illustrated on row 3 of FIG. 3b, whose inverse corresponds to the minimum latency of second specific signal path 205, as is apparent in comparison to the illustrated execution times 1 through 8 (there being eight in this exemplary embodiment) of the logic calculations in logic block 207. However, the minimum latency in the present case is smaller than the pattern of the input signal. In the present case (and in contrast to other advantageous specific embodiments described above), the specific downsampling factor is therefore not set to the smallest possible integral value (which would be n=6), with which the inverse of the effective clock rate would correspond to the minimum latency, but rather to a larger value, so that the inverse of the effective clock rate corresponds exactly to pattern W, i.e., to n=7 in the present case. The time response of the effective clock rate set in this way is illustrated in row 4 of FIG. 3b.

However, if the minimum latency and/or delay of the second specific signal path is greater than the pattern of the input signal, second specific signal path 205 in circuit design 201 may be divided into at least two partial signal paths, each having a minimum latency and/or delay which is/are smaller than the pattern (for example, by providing at least one additional register assigned to second specific signal path 205 in circuit design 201). The specific downsampling factor may then be set for second specific signal path 205 in such a way that the inverse of the effective clock rate is identical to the pattern.

For example, second specific signal path 205 may have a minimum latency of 200 ns, which is greater than the pattern of the input signal of 70 ns. Instead of setting the specific downsampling factor to the value n = 20, as had been possible in advantageous specific embodiments described above, second specific signal path 205 may be divided into three partial signal paths, which each have a minimum latency of 70 ns identical to the pattern. Also, n = 7 is set as the specific downsampling factor, and thus an effective clock rate is set, whose inverse corresponds to the pattern.

FIG. 3c shows, for this exemplary case and in reference to circuit design 201 from FIG. 3a, multiple diagrams having schematic time responses illustrated therein.

A time response of the base clock frequency is illustrated in row 1 of FIG. 3c, and a time response of the pattern of the input signal is illustrated in row 2 of FIG. 3c. A time response of a clock rate is illustrated in row 3 of FIG. 3c, whose inverse corresponds to the minimum latency of second specific signal path 205, as is apparent in comparison to the illustrated execution times 1 through 16 (there being 16 in this exemplary embodiment) of the logic calculations in logic block 207. However, the minimum latency in the present case is greater than the pattern of the input signal. In the present case, two registers are therefore inserted into second specific signal path 205, so that the minimum latency on the partial signal paths is identical to the pattern (70 ns), and the specific downsampling factor is set in the present case to a value so that the inverse of the effective clock rate corresponds directly to the pattern. A time response of the effective clock rate set in this way is illustrated in row 4 of FIG. 3c. Execution times 1 through 5 of logic calculations in block 207 take place during the clock cycle illustrated in row 4, execution times 6 through 1 of logical calculations in block 207 take place during the second clock cycle, and execution times 12 through 16 of logic calculations in block 207 take place during the third clock cycle. Logic calculations 1 through 16 were thus divided into three clocks of the effective clock rate.

An amount of a jitter of the input signal, such as a delay of the input signal caused by the jitter, may be viewed as the characteristic value of the input signal as an alternative or in addition to the pattern. The specific downsampling factor for second specific signal path 205, and thus the effective clock rate of the second specific signal path, may then be set partially based on the amount of the jitter. In a large modular system, for example, jitter may occur at the runtime of the system. Under certain circumstances, a delay as a sign of jitter may result due to a longer cable.

For example, a specific signal path (such as a first specific signal path) may be optimized, as was explained, for example, farther above in reference to circuit designs 1 and 101 in FIGS. 1a and 2a, i.e., a specific downsampling factor and thus an effective clock rate are set for the particular specific signal path. Timing errors may occur in the particular specific signal path, or the amount of the jitter (in particular, if this amount is known in advance) may be outside a defined permissibility range at runtime (i.e., in the FPGA), due to the jitter of an input signal. The specific signal path may then be advantageously treated as a second specific signal path, as was explained above in reference to the circuit design in FIG. 3a.

The specific downsampling factor selected for the particular specific signal path (initially without taking the jitter into account) may also be set to a smaller value, the reduction of the specific downsampling factor taking place at least partially based on the amount of the jitter. Alternatively or additionally, the specific downsampling factor selected for the particular specific signal path may then be set in such a way that the inverse of the effective clock rate has a smaller value than the pattern. A timing error caused by the jitter may be avoided thereby at runtime.

FIG. 3d shows, for this exemplary case and in reference to circuit design 201 from FIG. 3a, multiple diagrams having schematic time responses illustrated therein.

A time response of the base clock frequency is illustrated in row 1 of FIG. 3d, and a time response of a clock rate is illustrated in row 2 of FIG. 3d, whose inverse corresponds directly to the minimum latency of second specific signal path 205, as is apparent in comparison to the illustrated execution times 1 through 10 (there being 10 in this exemplary embodiment) of the logic calculations in logic block 207. A time response of a clock rate is illustrated in row 3 of FIG. 3d, which correspond to the one in row 2, but with a shifted starting time.

A time response of a clock rate is illustrated in row 4 of FIG. 3d, which correspond to the one in row 3. However, the specific signal path here is triggered with jitter. This may occur if the path is executed (“enabled”), for example, upon a “New Data” signal of an analog-in channel, which is connected, for example, via a bus to be arbitrated and thus may be delayed. In this case, the signal occurs up to one clock later, in this case after eight clocks, as indicated by the hatched area in row 4. The following value, however, may thus arrive one clock earlier than the clock period, after six clocks in this case. The effective clock rate of the multi-cycle path must be limited accordingly to six clocks in this case, i.e., n = 6 must be set as the specific downsampling factor so that no timing errors occur at runtime with respect to second specific signal path 205. The specific downsampling factor set to n=7 in this example would disrupt the timing, since the tenth execution time may not be completed if the next clock (the next chip enable signal) may already arrive after six clocks.

The setting of a smaller specific downsampling factor is advantageously associated with the provision of at least one further register in the second specific signal path. The logic calculations were thus distributed to at least two clocks of the effective clock rate (taking the jitter into account).

In specific embodiments, the second specific signal path may be identical to one of the specific signal paths described above, in particular to a first specific signal path.

FIG. 4 shows a flowchart 300 of a method according to the first aspect of the invention.

A circuit design to be mapped in an FPGA is provided in 301.

A timing analysis is at least partially carried out in 303 for at least a part of the circuit design to be mapped.

One or multiple signal paths of the circuit design is/are selected in 305 as the at least two first specific signal paths from among the signal paths of the circuit design to be mapped for which the timing error is detected during the timing analysis.

In 307, the at least one specific signal path is defined in the circuit design to be mapped as a multi-cycle path having an effective clock rate. For this purpose, the effective clock rate is set in 307b at least partially and/or at least implicitly based on a specific downsampling factor in the circuit design, which is applied to a base clock frequency at which the at least one specific signal path is clocked as standard according to the circuit design to be mapped.

A particularly preferred method is thus given for carrying out an optimization of the at least one specific signal path of the circuit design to be mapped in the FPGA.

FIG. 5 shows software 401 according to the second aspect of the invention.

Software 401 is provided for generating a circuit design to be mapped in an FPGA. The software may be configured to carry out a method according to the first aspect of the invention, as was described, for example, in the preceding description and, in particular, based on flowchart 300 illustrated in FIG. 4.

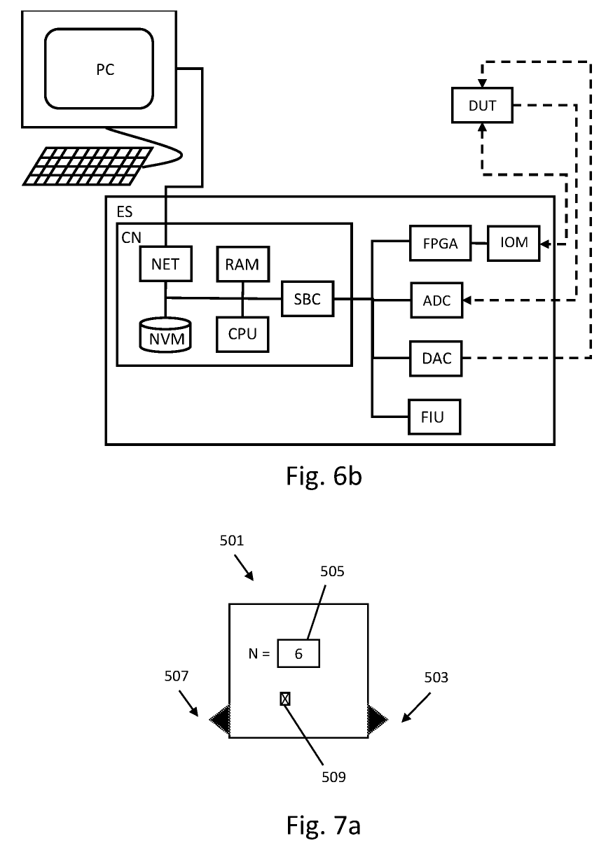

FIG. 6a shows a device for processing data 403 according to the third aspect of the invention.

Device for processing data 403 is configured to carry out a method according to the first aspect of the invention, as was described, for example, in the preceding description and, in particular, based on flowchart 300 illustrated in FIG. 4. Alternatively or additionally, device for processing data 403 may be configured to execute software according to the second aspect of the invention, as described in reference to software 401 illustrated in FIG. 5.

FIG. 6b shows a schematic representation of a hardware-in-the-loop test environment.

An example of a hardware-in-the-loop test environment is illustrated schematically in FIG. 6b, comprising an operating computer PC, a simulator ES, and a control unit DUT to be tested. Operating computer PC may be designed as a commercially available personal computer, comprising a screen, input devices, and one or multiple network interfaces. Operating computer PC may be advantageously configured to carry out a method according to the first aspect of the invention. For example, operating computer PC may be a device for processing data according to the third aspect of the invention, such as device for processing data 403 described above in reference to FIG. 6a.

Real-time simulator ES comprises a compute node CN, which is connected to operating computer PC via a network interface NET. Compute node CN includes at least one processor CPU, in particular a multicore processor, a random-access memory RAM, and a non-volatile memory NVM, in which an operating system and/or a boot loader is/are preferably stored. A logic board having a programmable logic chip FPGA, two I/O circuits ADC, DAC, and an error simulation circuit FIU is connected to the compute node via a high-speed bus SBC or a corresponding controller. Programmable logic chip FPGA is preferably freely programmable; for this purpose, in particular, a circuit design according to the invention or an optimized circuit design according to the present invention may be mapped therein. It may also be provided that simulator ES includes multiple logic boards or multiple programmable logic chips FPGA on a logic board. The logic board preferably has one or multiple slots for I/O modules. An I/O module IOM is illustrated, which is connected to control unit DUT to be tested and may exchange, for example, digital input and output signals therewith. I/O circuit ADC includes one or multiple analog/digital converters, which receive(s) the analog signals of control unit DUT to be tested. Simulator ES may output analog signals to control unit DUT to be tested via I/O circuit DAC, which includes one or multiple digital/analog converters. Error simulation circuit FIU may apply defined electrical errors to connected devices, such a short-circuit of two channels.

Freely programmable logic chips FPGA are used, in particular, for applications such as e-drives and power electronics, because particularly fast control loops occur there. Logic boards with an FPGA of this type advantageously have multiple slots for I/O modules, for example dSPACE offers the DS6601 FPGA base board with five slots, which may be fitted with different I/O modules. For example, an analog/digital conversion having a high resolution may be added to an existing test environment by installing a new I/O model. I/O modules may also have different channels, such as the DS6651 multi-I/O modules, which each have six analog input and output channels with a 16-bit resolution and 16 digital input and output channels.

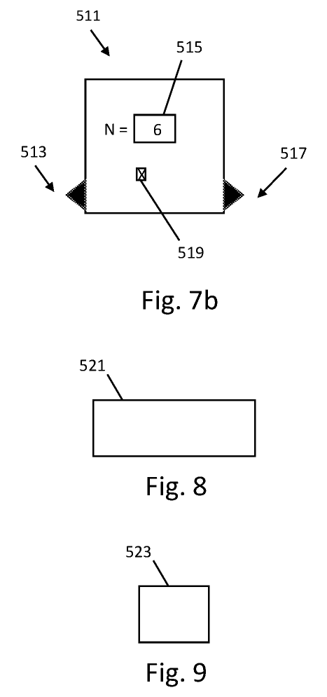

FIG. 7a shows a schematic representation of an input FPGA interface block 501 according to the fourth aspect of the invention.

Input FPGA interface block 501 is provided for use in software for generating a circuit design to be mapped in an FPGA. Input FPGA interface block 501 is designed to at least partially effectuate the fact that, when it is inserted into the circuit design to be mapped and its output side 503 is associated with a signal path of the circuit design, the signal path is subsequently clocked at an effective clock rate, at least in sections, which is lower than a base clock frequency at which the signal path would be clocked as standard according to the circuit design to be mapped. For example, input FPGA interface block 501 may at least partially induce an optimization to be carried out according to a method according to the first aspect of the invention, as described, for example, in the preceding description as well as based on flowchart 300 illustrated in FIG. 4.

A downsampling factor may be stored in input FPGA interface block 501 in that it is entered in input field 505. Alternatively or additionally, the downsampling factor may also be set based on a clock of a signal present or applicable to an input side 507 of block 501. Box 509 may be activated for this purpose. In this case, the chip enable signal from the source of the input value, i.e., the pattern of the analog-in converter, may be used. In the case of the analog-in, its “Data New,” for example, may be used as the chip enable signal for the particular specific signal path.

If box 509 is activated (for example, synchronously with “New Data” in the case of an input channel), the chip enable signals in the VHDL code may be automatically connected to the corresponding input chip enable sources in the circuit design during the build of the FPGA model.

FIG. 7b shows a schematic representation of an output FPGA interface block 511 according to the fifth aspect of the invention.

Output FPGA interface block 511 is provided for use in software for generating a circuit design to be mapped in an FPGA. Input FPGA interface block 511 is designed to at least partially effectuate the fact that, when it is inserted into the circuit design to be mapped and its input side 513 is associated with a signal path of the circuit design, the signal path is subsequently clocked at an effective clock rate, at least in sections, which is lower than a base clock frequency at which the signal path would be clocked as standard according to the circuit design to be mapped. For example, output FPGA interface block 511 may at least partially induce an optimization to be carried out according to a method according to the first aspect of the invention, as described, for example, in the preceding description as well as based on flowchart 300 illustrated in FIG. 4.

An upsampling factor may be stored in output FPGA interface block 511 in that it is entered in input field 515. Alternatively or additionally, the upsampling factor may also be set based on a clock of a signal present at or applicable to an output side 517 of block 511. Box 519 may be activated for this purpose.

if box 519 is activated (for example, synchronously with “TX Ready” in the case of an output channel), the chip enable signals in the VHDL code may be automatically connected to the corresponding output chip enable sources in the circuit design during the build of the FPGA model.

FIG. 8 shows a circuit design 521 to be mapped in an FPGA according to the sixth aspect of the invention. Circuit design 521 may be, for example, circuit design 1 described in reference to FIG. 1a or circuit design 101 described in reference to FIG. 2a.

FIG. 9 shows an FPGA 523, which includes a circuit design to be mapped therein, according to the seventh aspect of the invention. The circuit design may be, for example, a circuit design according to the sixth aspect of the invention, as described, for example, in reference to circuit design 521 illustrated in FIG. 8.

The features disclosed in the above description, in the drawings, and in the claims may be essential to the invention in its various specific embodiments, both individually and in any combination.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for carrying out an optimization of at least one specific signal path of a circuit design to be mapped in an FPGA, the method comprising:
at least partially carrying out a timing analysis for at least one part of the circuit design to be mapped;
selecting one or at least two signal paths of the circuit design as the at least one specific signal path from among signal paths of the circuit design to be mapped for which a timing error is determined during the timing analysis;
defining the at least one specific signal path in the circuit design to be mapped as a multi-cycle path having an effective clock rate that is different from a base clock frequency with which the at least one specific signal path is clocked as standard according to the circuit design to be mapped; and
setting the effective clock rate at least partially and/or at least implicitly based on a specific downsampling factor in the circuit design.

2. The method according to claim 1, wherein a delay of a data signal along the at least one specific signal path is at least implicitly ascertained, and the specific downsampling factor is set at least partially and/or at least implicitly based on the base clock frequency and/or the ascertained delay.

3. The method according to claim 1, wherein at least one interface in the circuit design is assigned to the specific signal path or is assigned at least one I/O interface and/or a model interface, via which the specific signal path is connected or connectable on an input side to at least one third signal path, which is clocked at a clock that is different from a base clock frequency, and/or whose signal value is provided to the specific signal path or at a rate that is different from the base clock frequency, and wherein the specific downsampling factor is set to a downsampling factor stored in the definition of the interface.

4. The method according to claim 1, wherein each of at least two first specific signal paths is defined in the circuit design to be mapped as a multi-cycle path, each having an identical effective clock rate.

5. The method according to claim 4, wherein a different delay of a signal along the particular first specific signal path is at least implicitly ascertained for each of the at least two first specific signal paths, and wherein the identical specific downsampling factor is set for the identical effective clock rate of the at least two first specific signal paths, at least partially and/or implicitly based on the base clock frequency and/or a delay corresponding to the maximum delay of the delays ascertained for the at least two first specific signal paths.

6. The method according to claim 5, wherein an integral downsampling factor is at least implicitly defined in each case for the at least two first specific signal paths, the particular downsampling factor describing in each case a ratio or an integral ratio of the basic clock frequency and an inverse of the minimum latency of the particular specific signal path.

7. The method according to claim 4, wherein at least one interface is assigned to the at least two first specific signal paths or at least one I/O interface and/or a model interface in each case, via which the particular first specific signal path is connected to at least one third signal path on the output side, the third signal paths each being clocked at clocks that are different from the basic clock frequency and are at least partially different from each other, and/or wherein the third signal paths expect, in each case, data at a rate that is different from the basic clock frequency and rates that are at least partially different from each other, wherein an upsampling factor for the particular first specific signal path assigned to the particular interface is stored for each interface in an associated interface definition, and, wherein, for the identical effective clock rate of the at least two first specific signal paths, the identical specific downsampling factor is set to the value corresponding to the highest value among all upsampling factors stored in the interface definitions.

8. The method according to claim 7, wherein, if the ratio of the greatest delay among the at least two first specific signal paths and the smallest delay among the at least two first specific signal paths is no more than a limit value or 1.3, the identical specific downsampling factor is set, for the identical effective clock rate of the at least two first specific signal paths, to a divisor or to the largest common divisor of all upsampling factors stored in the definitions of the interfaces assigned to the at least two first specific signal paths.

9. The method according to claim 4, wherein:
(i) if the relative and/or absolute difference between the largest and the smallest downsampling factor of the first specific signal paths is with a defined value range, and/or if at least one or all of the downsampling factors of the first specific signal paths is greater than one in each case, the at least two first specific signal paths are each defined as a multi-cycle path having the identical effective clock rate in each case; and/or
(ii) if the relative and/or absolute difference between the largest and the smallest downsampling factor of the first specific signal paths is outside the defined value range, and/or if at least one of the downsampling factors is one, then at least one or all of the at least two first specific signal paths is defined in each case as a multi-cycle path, with each having an effective clock rate based on a specific downsampling factor defined according to the particular first specific signal path.

10. The method according to claim 4, wherein the at least two first specific signal paths are ascertained in that an associated input block in the circuit design to be mapped is ascertained for an identified first, first specific signal path, and at least one further signal path, or a specific signal path, emanating from the ascertained input block and running in parallel in terms of signaling to the first first specific signal path, at least in sections, is ascertained and identified as the second first specific signal path.

11. The method according to claim 1, wherein an integral downsampling factor is at least implicitly defined for at least one or for at least two and/or for all of the specific signal paths, the particular downsampling factor describing in each case an, in particular integral, ratio of the base clock frequency and the inverse of the minimum latency of the particular specific signal path, and/or in relation to at least one or in relation to all of the specific signal paths, the definition of the particular specific signal path as a multi-cycle path includes in each case the fact that at least two circuit design blocks assigned to the particular specific signal path are provided within the circuit design, with the aid of which the clock rate for the particular specific signal path is set to the effective clock rate, and wherein a first circuit design block of the at least two circuit design blocks in each case is a downsampling block of the particular specific signal path in the circuit design and/or has its functionality, and/or the particular downsampling factor is stored in the first circuit design block, and/or a second circuit design block of the at least two circuit design blocks is an upsampling block of the particular specific signal path in the circuit design and/or has its functionality, and/or an upsampling factor corresponding to the particular downsampling factor is stored in the second circuit design block.

12. The method according to claim 11, wherein, in at least one or in at least two, and/or in all, of the specific signal paths, the first circuit design block is in each case an input FPGA interface block of the particular specific signal path in the circuit design to be mapped, via which the input-side interface of the particular specific signal path is provided, and/or wherein the second circuit design block is in each case an output FPGA interface block of the particular specific signal path in the circuit design to be mapped, via which the output-side interface of the particular specific signal path is provided.

13. The method according to claim 4, wherein the at least two first specific signal paths, which are each defined as a multi-cycle path, each having the identical effective clock rate, (i) emanate from a common circuit design block of the circuit design, which is or includes the at least one downsampling block and/or has its functionality, and, the common circuit design block is a common input FPGA interface block, and/or a downsampling factor is stored in the common circuit design block, which is set as the specific downsampling factor; and/or (ii) run in the direction of different circuit design blocks of the circuit design, which in each case are or include at least one upsampling block and/or have its functionality, of which at least one or all is an output FPGA interface block of the particular first specific signal path.

14. The method according to claim 1, wherein at least one interface or an I/O interface and/or a model interface in the circuit design is assigned to at least one second specific signal path, which is substantially identical to a specific signal path or to at least one of the at least one first specific signal paths, and the specific downsampling factor is set in the circuit design at least partially and/or at least implicitly depending on at least one characteristic value of an external input signal present at or applicable to the interface, the specific downsampling factor being stored in a definition of the interface, wherein (i) the characteristic value is a pattern of the input signal and/or an amount of a jitter of the input signal, such as a delay of the input signal caused by the jitter, and/or (ii) a minimum latency of at least one second specific signal path is ascertained, and the specific downsampling factor for the effective clock rate of the second specific signal path is also set depending on the ascertained minimum latency, and wherein the specific downsampling factor for the effective clock rate of the second specific signal path being set in such a way that the inverse of the effective clock rate is identical to the pattern of the input signal if the ascertained minimum latency and/or delay of the second specific signal path is smaller than or equal to the pattern of the input signal.

15. Software stored on a computer readable medium storing instructions that, when executed by a computer generate a circuit design to be mapped in an FPGA according to claim 1.
